(19) United States
(12) Patent Application Publication
(10) Pub. No.: US 2024/0347325 A1
(43) Pub. Date: Oct. 17, 2024

(54) PLASMA PROCESSING APPARATUS

(71) Applicant: Tokyo Electron Limited, Tokyo (JP)

(72) Inventors: Yuki ONODERA, Miyagi (JP); Takamitsu TAKAYAMA, Miyagi (JP)

(73) Assignee: Tokyo Electron Limited, Tokyo (JP)

(21) Appl. No.: 18/750,539

(22) Filed: Jun. 21, 2024

Related U.S. Application Data
(63) Continuation of application No. PCT/JP2022/047493, filed on Dec. 22, 2022.

(30) Foreign Application Priority Data
Dec. 23, 2021 (JP) 2021-209532

(51) Int. Cl. H01J 37/32; H01L 21/683

(52) U.S. Cl. CPC H01J 37/32862; H01J 37/32642; H01J 37/32715; H01J 2237/2007; H01L 21/6831

(57) ABSTRACT

A plasma processing apparatus includes: a stage having first and second placement surfaces; an elevating mechanism for raising and lowering a ring member on the second placement surface with respect to the second placement surface; a radio-frequency power source; and a controller for executing a cleaning process including an operation of separating the second placement surface and the ring member from each other by the elevating mechanism; and an operation of removing deposits accumulated on the stage and the ring member by supplying radio-frequency power from the radio-frequency power source to the stage to generate plasma. In the separation operation, a distance between the second placement surface and the ring member is set such that a density of plasma generated in a region between an outer edge of the first placement surface and a lower surface of the ring member is higher than that of plasma generated in other regions.

### CROSS-REFERENCE TO RELATED APPLICATIONS

This application is a bypass continuation application of international application No. PCT/JP2022/047493 having an international filing date of Dec. 22, 2022, and designating the United States, the international application being based upon and claiming the benefit of priority from Japanese Patent Application No. 2021-209532, filed on Dec. 23, 2021, the entire contents of each are incorporated herein by reference.

### TECHNICAL FIELD

The present disclosure relates to a plasma processing apparatus.

### BACKGROUND

In the related art, in a plasma processing apparatus, there is known a technique for removing, by plasma, deposits accumulated on a stage on which an edge ring surrounding an outer periphery of a substrate placement surface is placed, and the edge ring placed on the stage in a state in which the edge ring is spaced apart from the stage.

### PRIOR ART DOCUMENT

### Patent Document

Patent Document 1: Japanese Laid-Open Patent Publication No. 2012-146743
Patent Document 2: Japanese Laid-Open Patent Publication No. 2019-201047

### SUMMARY

According to an aspect of the present disclosure, a plasma processing apparatus includes: a stage having a first placement surface on which a substrate is placed, and a second placement surface on which a ring member surrounding an outer periphery of the first placement surface is placed; an elevating mechanism configured to raise and lower the ring member with respect to the second placement surface; a radio-frequency power source connected to the stage; and a controller, wherein the controller is configured to execute a cleaning process that includes: a separation operation of separating the second placement surface and the ring member from each other by the elevating mechanism; and subsequently, a removal operation of removing deposits accumulated on the stage and the ring member by supplying radio-frequency power from the radio-frequency power source to the stage to generate plasma. In the separation operation, a separation distance between the second placement surface and the ring member is set such that a first density of the plasma generated in a first region between an outer edge of the first placement surface and an inner edge of a lower surface of the ring member is higher than a second density of the plasma generated in a second region.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a system configuration diagram showing an example of a substrate processing system according to a first embodiment of the present disclosure.

FIG. 2 is a schematic cross-sectional view showing a configuration of a PM according to the first embodiment.

FIG. 3 is a flowchart showing an example of a flow of a cleaning process according to the first embodiment.

FIG. 4 is a diagram showing an example of a distribution of plasma generated when radio-frequency power is supplied in a state in which an edge ring is placed on a second placement surface.

FIG. 5 is a diagram showing an example of a distribution of plasma generated when the radio-frequency power is supplied in a state in which the edge ring is spaced apart from the second placement surface.

FIG. 6 is a graph showing a relationship between a height of a lower surface of the edge ring with respect to a first placement surface when the edge ring is spaced apart from the second placement surface, and an etching rate of a resist film at positions of the stage and the edge ring.

FIG. 7 is a flowchart showing an example of a flow of a cleaning process according to Modification 1 of the first embodiment.

FIG. 8 is a flowchart showing an example of a flow of a cleaning process according to Modification 2 of the first embodiment.

FIG. 9 is a schematic cross-sectional view showing an example of a structure of a PM according to a second embodiment.

FIG. 10 is an enlarged cross-sectional view showing an example of a structure near an edge of an electrostatic chuck.

FIG. 11 is a flowchart showing an example of a flow of a cleaning process according to the second embodiment.

FIG. 12 is a flowchart showing an example of a flow of a cleaning process according to Modification 1 of the second embodiment.

FIG. 13 is a flowchart showing an example of the flow of a cleaning process according to Modification 2 of the second embodiment.

FIG. 14 is a flowchart showing an example of a flow of a cleaning process according to Modification 3 of the second embodiment.

FIG. 15 is a flowchart showing an example of a flow of a cleaning process according to Modification 4 of the second embodiment.

FIG. 16 is a flowchart showing an example of a flow of a cleaning process according to Modification 5 of the second embodiment.

FIG. 17 is a flowchart showing an example of a flow of a cleaning process according to Modification 6 of the second embodiment.

FIG. 18 is a flowchart showing an example of a flow of a cleaning process according to Modification 7 of the second embodiment.

FIG. 19 is a flowchart showing an example of a flow of a cleaning process according to Modification 8 of the second embodiment.

FIG. 20 is a flowchart showing an example of a flow of a cleaning process according to Modification 9 of the second embodiment.

FIG. 21 is a flowchart showing an example of a flow of a cleaning process according to Modification 10 of the second embodiment.

### DETAILED DESCRIPTION

Hereinafter, embodiments of a plasma processing apparatus and a cleaning method disclosed herein will be described in detail with reference to the drawings. Further, the present disclosure is not limited to these embodiments. Respective embodiments may be combined as appropriate to the extent that they are not contradictory. Further, in the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

When a plasma process is performed using a plasma processing apparatus, deposits formed of reaction products such as a CF-based polymer and the like are accumulated on a substrate placement surface of a stage. The accumulation of the deposits on the substrate placement surface may cause abnormalities such as poor attraction of a substrate. For this reason, in the plasma processing apparatus, a dry cleaning of removing the deposits accumulated on the substrate placement surface by the plasma process is performed.

For example, when a diameter of the substrate placement surface is smaller than that of the substrate, reaction products caused by a processing gas used for the plasma process may enter between an outer periphery of the stage and a back surface of the wafer. Thus, the deposits may be locally accumulated on the outer periphery of the stage. Further, a ring member such as an edge ring or the like surrounding the substrate placement surface is arranged around the outer periphery of the stage with a small distance left from the outer periphery of the stage. As a result, as the reaction products enter a region between the outer periphery of the stage and an inner periphery of the ring member, deposits may also be locally accumulated on the outer periphery of the stage, the inner periphery of the ring member, and the lower surface of the ring member. However, since the region between the outer periphery of the stage and the inner periphery of the ring member is narrow, it is difficult for plasma to enter the region between the outer periphery of the stage and the inner periphery of the ring member, and the lower surface of the ring member as compared to other regions. Therefore, deposits tend to remain on the outer periphery of the stage, the inner periphery of the ring member and the lower surface of the ring member after the dry cleaning.

As described above, deposits tend to accumulate more easily on the outer periphery of the stage, the inner periphery of the ring member and the lower surface of the ring member than on other regions.

In order to remove the deposits accumulated on the outer periphery of the stage, the inner periphery of the ring member and the lower surface of the ring member, it is conceivable to prolong, for example, a dry cleaning time. However, when the dry cleaning time is prolonged, damage to the stage may be increased, which may shorten the lifespan of the stage.

Therefore, it is expected to remove the deposits accumulated on the outer periphery of the stage, the inner periphery of the ring member and the lower surface of the ring member while suppressing the damage to the stage.

### First Embodiment

### [Configuration of Substrate Processing System 50]

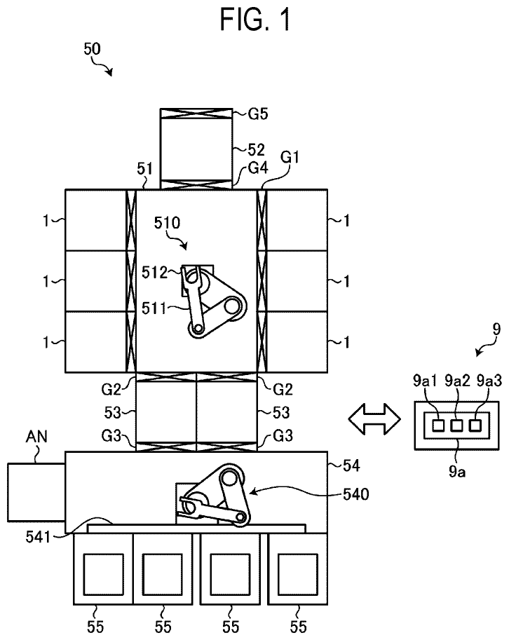

FIG. 1 is a system configuration diagram showing an example of a substrate processing system 50 according to a first embodiment of the present disclosure. The substrate processing system 50 includes a VTM (Vacuum Transfer Module) 51, an accommodation device 52, a plurality of LLMs (Load Lock Modules) 53, an EFEM (Equipment Front End Module) 54, and a plurality of PMs (Process Modules) 1. The PMs 1 are connected to sidewalls of the VTM 51 via gate valves G1. In the example of FIG. 1, six PMs 1 are connected to the VTM 51, but the number of PMs 1 connected to the VTM 51 may be more than six or less than six. The VTM 51 is an example of a vacuum transfer device.

Each of the PMs 1 performs a process such as etching or film formation using plasma on a wafer W (one example of the substrate) to be processed. The plurality of LLMs 53 are connected to another sidewall of the VTM 51 via gate valves G2. In the example of FIG. 1, two LLMs 53 are connected to the VTM 51. However, the number of LLMs 53 connected to the VTM 51 may be more than two or may be one.

A transfer robot 510 is arranged inside the VTM 51. The transfer robot 510 is an example of a transfer device. The transfer robot 510 includes an arm 511 and a fork 512. The fork 512 is provided at the tip of the arm 511. A wafer W, an edge ring, and a dummy wafer (an example of a dummy substrate) are placed on the fork 512. The transfer robot 510 transfers the wafer W between the PM 1 and another PM 1 and between the PM 1 and the LLM 53. Further, the transfer robot 510 transfers the edge ring and the dummy wafer between the PM 1 and the accommodation device 52. An interior of the VTM 51 is maintained at a predetermined pressure lower than an atmospheric pressure.

The VTM 51 is connected to one sidewall of each LLM 53 via a gate valve G2, and the EFEM 54 is connected to the other sidewall of each LLM 53 via a gate valve G3. When the wafer W is loaded into the LLM 53 from the EFEM 54 via the gate valve G3, the gate valve G3 is closed and an internal pressure of the LLM 53 is lowered to a pressure approximately equal to an internal pressure of the VTM 51. Then, the gate valve G2 is open, and the wafer W in the LLM 53 is transferred into the VTM 51 by the transfer robot 510.

Further, while the internal pressure of the LLM 53 is approximately equal to the internal pressure of the VTM 51, the transfer robot 510 loads the wafer W from the VTM 51 into the LLM 53 via the gate valve G2. The gate valve G2 is closed. Then, the internal pressure of the LLM 53 is raised a pressure approximately equal to the internal pressure of the EFEM 54. Then, the gate valve G3 is open, and the wafer W inside the LLM 53 is unloaded into the EFEM 54.

A plurality of load ports 55 are provided on a sidewall of the EFEM 54 on which the gate valve G3 is provided and another sidewall of the EFEM 54 opposite to that sidewall. A container such as a FOUP (Front Opening Unified Pod) capable of accommodating a plurality of wafers W is connected to each load port 55.

The interior of the EFEM 54 is kept at, for example, the atmospheric pressure. A transfer robot 540 is provided inside the EFEM 54. The transfer robot 540 moves inside the EFEM 54 along a guide rail 541 provided inside the EFEM 54 and transfers the wafer W between the LLM 53 and the container connected to the load port 55. An FFU (Fan Filter Unit) or the like is provided at the top of the EFEM 54, and a dry air from which particles and the like have been removed is supplied from the top into the EFEM 54 to form a down-flow inside the EFEM 54. In the present embodiment, the internal pressure of the EFEM 54 is the atmospheric pressure. In another embodiment, the internal pressure of the EFEM 54 may be controlled to be a positive pressure. Accordingly, it is possible to suppress particles or the like from entering into the EFEM 54 from the outside.

An aligner AN is connected to the EFEM 54. The aligner AN is configured to adjust a position of the wafer W. The aligner AN may be configured to adjust a position of the edge ring. The aligner AN may be provided inside the EFEM 54.

The accommodation device 52 is connected to another sidewall of the VTM 51 via a gate valve G4. The accommodation device 52 accommodates the edge ring and the dummy wafer. In the present embodiment, the accommodation device 52 accommodates an edge ring for replacement, a used edge ring, and the dummy wafer. The accommodation device 52 has a function of switching an internal pressure of the accommodation device 52 between the atmospheric pressure and the pressure approximately equal to the internal pressure of the VTM 51. The edge ring for replacement may be a new edge ring, or may be a used edge ring with a small amount of wear.

For example, the gate valve G4 is open while the interior of the accommodation device 52 has the pressure approximately equal to the internal pressure of the VTM 51, and the used edge ring is accommodated from the PM 1 in the accommodation device 52 via the VTM 51 by the transfer robot 510. Then, the edge ring for replacement is loaded into the PM 1 from the accommodation device 52 via the VTM 51 by the transfer robot 510. Then, the gate valve G4 is closed, and the internal pressure of the accommodation device 52 is switched from the pressure approximately equal to the internal pressure of the VTM 51 to the atmospheric pressure. Thereafter, the gate valve G5 is open, and the used edge ring is unloaded to the outside of the accommodation device 52 via the gate valve G5. Then, the edge ring for replacement is loaded into the accommodation device 52 via the gate valve G5.

For example, the gate valve G4 is open while the internal pressure of the accommodation device 52 is approximately equal to the internal pressure of the VTM 51, and the dummy wafer is loaded into the PM 1 by the transfer robot 510 via the VTM 51. After the cleaning for the interior of the PM 1 is completed, the transfer robot 510 returns the PM 1 to the accommodation device 52. When the dummy wafer is replaced, for example, the internal pressure of the accommodation device 52 is switched from the pressure approximately equal to the internal pressure of the VTM 51 to the atmospheric pressure. Thereafter, the gate valve G5 is open, and the dummy wafer is unloaded to the outside of the accommodation device 52 through the gate valve G5. Then, a dummy wafer for replacement is loaded into the accommodation device 52 via the gate valve G5. The dummy wafer for replacement may be a new dummy wafer or a used dummy wafer with a small amount of wear.

The controller 9 processes computer-executable instructions that cause the substrate processing system 50 to execute various operations described in the present disclosure. The controller 9 may be configured to control each element of the substrate processing system 50 to execute the various operations described herein. In one embodiment, the controller 9 may be partially or entirely included in the substrate processing system 50. The controller 9 may include a processor 9a1, a memory 9a2, and a communication interface 9a3. The controller 9 is implemented by, for example, a computer 9a. The processor 9a1 may be configured to perform various control operations by reading a program from the memory 9a2 and executing the read program. This program may be stored in advance in the memory 9a2, or may be acquired via a medium if necessary. The acquired program is stored in the memory 9a2, and is read out from the memory 9a2 and executed by the processor 9a1. The medium may be various storage media readable by the computer 9a, or may be a communication line connected to the communication interface 9a3. The processor 9a1 may be a CPU (Central Processing Unit). The memory 9a2 may include a RAM (Random Access Memory), a ROM (Read Only Memory), an HDD (Hard Disk Drive), an SSD (Solid State Drive), or a combination thereof. The communication interface 9a3 may communicate with the substrate processing system 50 via a communication line such as a LAN (Local Area Network) or the like.

### [Configuration of Plasma Processing Apparatus]

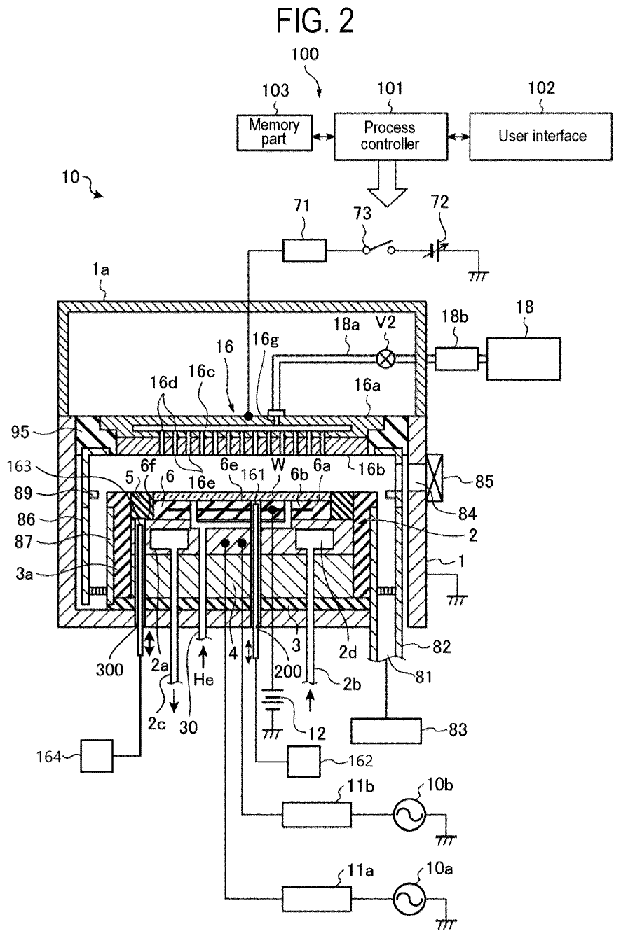

FIG. 2 is a schematic cross-sectional view showing a configuration of the PM 1 according to the first embodiment. The PM 1 is an example of a plasma processing apparatus. In the present embodiment, the PM 1 is a capacitively coupled plasma processing apparatus. The PM 1 includes a processing container (also referred to as a “plasma processing chamber” as appropriate) 10 configured to be airtight and electrically connected to a ground potential. The processing container 10 has a cylindrical shape and is made of, for example, aluminum. The processing container 10 defines a processing space in which plasma is generated. A stage 2 is provided inside the processing container 10 to horizontally support a semiconductor wafer (hereinafter simply referred to as a “wafer”) W, which is a substrate (workpiece). The stage 2 includes a base 2a and an electrostatic chuck (ESC) 6.

The base 2a is made of a conductive metal such as aluminum or the like, and has a function as a lower electrode. The base 2a is supported by an insulating support stand 4. The support stand 4 is supported by a support member 3 made of, for example, quartz.

The electrostatic chuck 6 has a disk shape with a flat upper surface constituting a first placement surface 6e on which the wafer W is placed. The electrostatic chuck 6 is provided at the center of the stage 2 in a plan view. The electrostatic chuck 6 is configured by an electrode 6a interposed between insulators 6b. A DC power source 17 is connected to the electrode 6a. By applying a DC voltage from the DC power source 17 to the electrode 6a, the wafer W is electrostatically attracted by virtue of a Coulomb force.

In the present embodiment, as an example, a diameter of the first placement surface 6e is slightly smaller than the diameter of the wafer W.

The upper outer periphery of the stage 2 forms a second placement surface 6f. The second placement surface 6f surrounds the first placement surface 6e and is formed at a lower position than the first placement surface 6e. An edge ring 5 made of, for example, monocrystalline silicon is arranged on the second placement surface 6f. The edge ring 5 is formed in an annular shape and is arranged on the second placement surface 6f so as to surround the outer periphery of the first placement surface 6e of the stage 2. Inside the processing container 10, a cylindrical inner wall member 3a made of, for example, quartz, is provided to surround the stage 2 and the support stand 4.

A first RF power source 14a is connected to the base 2a via a first matcher 15a, and a second RF power source 14b is connected to the base 2a via a second matcher 15b. The first RF power source 14a is a power source for plasma generation. Radio-frequency power having a predetermined frequency is supplied to the base 2a of the stage 2 from the first RF power source 14a. The second RF power source 14b is a power source for ion attraction (for bias). The second RF power source 14b supplies radio-frequency power having a predetermined frequency lower than that of the first RF power source 14a to the base 2a of the stage 2. In this way, the stage 2 is configured so that a voltage can be applied thereto. On the other hand, a shower head 16 functioning as an upper electrode is provided above the stage 2 so as to face the stage 2 in parallel. The shower head 16 and the stage 2 function as a pair of electrodes (the upper electrode and the lower electrode).

A temperature-control medium flow path 2d is formed inside the stage 2. An inlet pipe 2b and an outlet pipe 2c are connected to the temperature-control medium flow path 2d. A temperature of the stage 2 may be controlled to a predetermined temperature by circulating an appropriate temperature-control medium, such as cooling water, in the temperature-control medium flow path 2d. Further, a gas supply pipe 130 for supplying a heat transfer gas (backside gas) such as a helium gas or the like to the back surface of the wafer W is provided so as to penetrate through the stage 2 and the like. The gas supply pipe 130 is connected to a gas source (not shown). With these configurations, the temperature of the wafer W attracted and held on the upper surface of the stage 2 by the electrostatic chuck 6 is controlled to a predetermined temperature.

The stage 2 is provided with a plurality of, for example, three, pin through-holes 200 (only one of which is shown in FIG. 2). Lift pins 161 are disposed inside these pin through-holes 200, respectively. The lift pins 161 are connected to an elevating mechanism 162. The elevating mechanism 162 raises and lowers the lift pins 161 so that the lift pins 161 moves up and down with respect to the first placement surface 6e of the stage 2. When the lift pins 161 are raised, the tips of the lift pins 161 protrude from the first placement surface 6e of the stage 2 so that the wafer W is held above the first placement surface 6e of the stage 2. On the other hand, when the lift pins 161 are lowered, the tips of the lift pins 161 are accommodated in the pin through-holes 200 so that the wafer W is placed on the first placement surface 6e of the stage 2. In this way, the elevating mechanism 162 raises and lowers the wafer W with respect to the first placement surface 6e of the stage 2 using the lift pins 161. Further, when the lift pins 161 are raised, the elevating mechanism 162 holds the wafer W above the first placement surface 6e of the stage 2 by the lift pins 161.

Further, the stage 2 is provided with a plurality of, for example, three, pin through-holes 300 (only one of which is shown in FIG. 2). Lift pins 163 are disposed inside these pin through-holes 300, respectively. The lift pins 163 are connected to an elevating mechanism 64. The elevating mechanism 164 raises and lowers the lift pins 163 so that the lift pins 163 moves up and down with respect to the second placement surface 6f of the stage 2. When the lift pins 163 are raised, the tips of the lift pins 163 protrude from the second placement surface 6f of the stage 2 so that the edge ring 5 is held above the second placement surface 6f of the stage 2. On the other hand, when the lift pins 163 are lowered, the tips of the lift pins 163 are accommodated in the pin through-holes 300 so that the edge ring 5 is placed on the second placement surface 6f of the stage 2. In this way, the elevating mechanism 164 raises and lowers the edge ring 5 with respect to the second placement surface 6f of the stage 2 using the lift pins 163. Further, when the lift pins 163 are raised, the elevating mechanism 164 holds the edge ring 5 above the second placement surface 6f of the stage 2 by the lift pins 163.

The shower head 16 described above is provided on a top wall of the processing container 10. The shower head 16 includes a main body portion 16a and an upper top plate 16b serving as an electrode plate, and is supported on the upper portion of the processing container 10 via an insulating member 95. The main body portion 16a is made of a conductive material, for example, aluminum whose surface has been anodized, and is configured such that the upper top plate 16b may be detachably supported under the main body portion 16a.

The main body portion 16a is provided with a gas diffusion chamber 16c therein. Further, the main body portion 16a has a large number of gas flow holes 16d formed at the bottom thereof so as to be located below the gas diffusion chamber 16c. Further, the upper top plate 16b is provided with gas introduction holes 16e formed to extend through the upper top plate 16b in a thickness direction and overlap the above-mentioned gas flow holes 16d. With this configuration, the processing gas supplied to the gas diffusion chamber 16c is distributed and supplied into the processing container 10 in the form of a shower via the gas flow holes 16d and the gas introduction holes 16e.

A gas introduction port 16g for introducing the processing gas into the gas diffusion chamber 16c is formed in the main body portion 16a. One end of a gas supply pipe 18a is connected to the gas introduction port 16g. A gas source (gas supplier) 15 that supplies the processing gas is connected to the other end of the gas supply pipe 18a. The gas supply pipe 18a is provided with a mass flow controller (MFC) 18b and an on-off valve V2 which are arranged in the named order from the upstream side. A processing gas for plasma etching is supplied from the gas source 18 to the gas diffusion chamber 16c via the gas supply pipe 18a. The processing gas is supplied into the processing container 10 from the gas diffusion chamber 16c in the form of a shower via the gas flow holes 16d and the gas introduction holes 16e.

A variable DC power source 72 is electrically connected to the shower head 16 as the upper electrode via a low pass filter (LPF) 71. The variable DC power source 72 is configured such that power supply may be turned on and off by an on/off switch 73. The current and voltage of the variable DC power source 72 and the on/off state of the on/off switch 73 are controlled by a controller 100, which will be described later. As will be described later, when radio-frequency waves are applied to the stage 2 from the first RF power source 14a and the second RF power source 14b to generate plasma in the processing space, the controller 100 may turn on the on/off switch 73 as needed. As a result, a predetermined DC voltage is applied to the shower head 16 as the upper electrode.

A cylindrical ground conductor 10c is provided to extend from the sidewall of the processing container 10 above a height position of the shower head 16. This cylindrical ground conductor 10c includes a ceiling wall at its upper portion.

An exhaust port 81 is formed at the bottom of the processing container 10. A first exhaust device 83 is connected to the exhaust port 81 via an exhaust pipe 82. The first exhaust device 83 includes a vacuum pump, and is configured to be able to reduce the internal pressure of the processing container 10 to a predetermined degree of vacuum by operating this vacuum pump. On the other hand, a loading/unloading port 84 for the wafer W is provided in the sidewall of the processing container 10, and a gate valve 85 for opening and closing the loading/unloading port 84 is provided at the loading/unloading port 84. The gate valve 85 corresponds to the gate valve G1 shown in FIG. 1.

A deposits shield 86 is provided inward of a side portion of the processing container 10 along an inner wall surface of the processing container 10. The deposits shield 86 prevents etching byproducts (deposits) from adhering to the processing container 10. A conductive member (GND block) 89 connected to the ground so that its potential can be controlled is provided at approximately the same height as the wafer W on the deposits shield 86, thereby preventing abnormal discharge. Further, a deposits shield 87 extending along the inner wall member 3a is provided at a lower end portion of the deposits shield 86. The deposits shields 86 and 87 are detachable.

The operation of the PM 1 having the above configuration is totally controlled by the controller 100. The controller 100 is provided with a process controller 101 that includes a CPU and controls each part of the PM 1, a user interface 102, and a memory 103.

The user interface 102 includes a keyboard through which a process manager inputs commands to manage the PM 1, a display that visually displays the operation situation of the PM 1, and the like.

The memory 103 stores recipes that include control programs (software) for implementing various processes executed by the PM 1 under the control of the process controller 101, processing condition data, and the like. Then, if necessary, by calling an arbitrary recipe from the memory 103 according to an instruction from the user interface 102 and causing the process controller 101 to execute the recipe, a desired process is performed in the PM 1 under the control of the process controller 101. It is also possible to use recipes such as control programs and processing condition data stored in a non-transitory computer-readable computer storage medium (e.g., a hard disk, a CD, a flexible disk, a semiconductor memory, etc.). In addition, recipes such as control programs and processing condition data may be transmitted from another device at any time, for example, via a dedicated line, and may be used in an online environment.

In the above example, the PM 1 is controlled by the controller 100. However, the PM 1 may be connected to the controller 9 of the substrate processing system 50 and may be controlled by the controller 9. In this case, the controller 9 may be configured integrally with the controller 100 or may be configured separately from the controller 100. Further, the PM 1 may be controlled in cooperation between the controller 100 and the controller 9.

[One Example of the Flow of the Cleaning Process according to the First Embodiment]

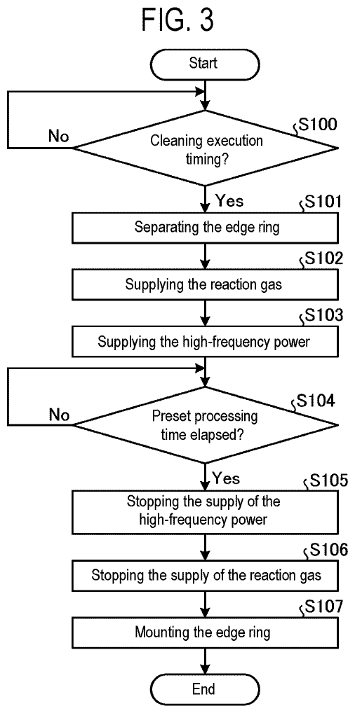

Next, the flow of the cleaning process executed by the PM 1 according to the first embodiment will be described with reference to FIG. 3. FIG. 3 is a flowchart showing one example of the flow of the cleaning process according to the first embodiment. The cleaning process shown in FIG. 3 is implemented mainly by the PM 1 operating under the control of the controller 100. Further, the cleaning process shown in FIG. 3 is executed in a state where no wafer W is accommodated in the processing container 10.

First, the controller 100 determines whether or not it is a timing to execute the cleaning process (S100). The timing to execute the cleaning process may be, for example, a timing at which the execution of a process such as plasma etching is completed for a predetermined number of wafers W. When it is determined that the timing to execute the cleaning process has not arrived (S100: No), the process of step S100 is executed again.

On the other hand, when it is determined that the timing to execute the cleaning process has arrived (S100: Yes), the edge ring 5 is separated from the second placement surface 6f by raising (pining up) the lift pins 163 (S101). Information on the separation distance between the edge ring 5 and the second placement surface 6f is stored, for example, in the memory 103 in advance. The controller 100 raises the lift pins 163 according to the information stored in the memory 103.

Subsequently, after the interior of the processing container 10 is depressurized to a predetermined degree of vacuum by the first exhaust device 83, a reaction gas is supplied into the processing container 10 from the gas source 18 via the gas supply pipe 18a (S102). In the present embodiment, when the deposits to be cleaned is a CF-based polymer, the reaction gas supplied from the gas source 18 is an O₂ gas. The reaction gas is not limited to the O₂ gas, but may be other oxygen-containing gases such as a CO gas, a CO₂ gas, and an O₃ gas. Further, when the deposits contains silicon or metal in addition to the CF-based polymer, for example, a halogen-containing gas may be added to the O₂ gas as the reaction gas. The halogen-containing gas is, for example, a fluorine-based gas such as a CF₄ gas or an NF₃ gas. Further, the halogen-containing gas may be a chlorine-based gas such as a Cl₂ gas, or a bromine-based gas such as an HBr gas. Thus, in the cleaning process, the oxygen-containing gas is used as the reaction gas.

Subsequently, radio-frequency power is supplied to the stage 2, which is the lower electrode (S103). In step S103, the controller 100 controls the first RF power source 14a and the second RF power source 14b to generate the radio-frequency power, thereby supplying the radio-frequency power to the base 2a of the stage 2. Further, the controller 100 applies the DC power supplied from the variable DC power source 72 to the shower head 16 by turning on the on/off switch 73. As a result, plasma of the oxygen-containing gas is generated inside the processing container 10. Frequencies of the radio-frequency power generated by each of the first RF power source 14a and the second RF power source 14b are not particularly limited. Although there has been shown the example in which the PM 1 includes the first RF power source 14a and the second RF power source 14b, the PM 1 does not necessarily need to include the second RF power source 14b. Further, although there has been shown the example in which the PM 1 includes the variable DC power source 72, the PM 1 does not necessarily need to include the variable DC power source 72.

Subsequently, the controller 100 determines whether or not a preset processing time has elapsed since the start of the supply of the radio-frequency power in step S103 (S104). When it is determined that the preset processing time has not elapsed (S104: No), the process of step S104 is executed again.

On the other hand, when it is determined that the preset processing time has elapsed (S104: Yes), the supply of the radio-frequency power to the stage 2 is stopped (S105). Further, the supply of the reaction gas into the processing container 10 is stopped (S106). As a result, the generation of the plasma of the oxygen-containing gas inside the processing container 10 is stopped.

After the reaction gas in the processing container 10 is exhausted, the edge ring 5 is placed on the second placement surface 6f by lowering the lift pins 163. This completes the cleaning method shown in the flowchart.

### [As for Plasma Generated in the Cleaning Process According to the First Embodiment]

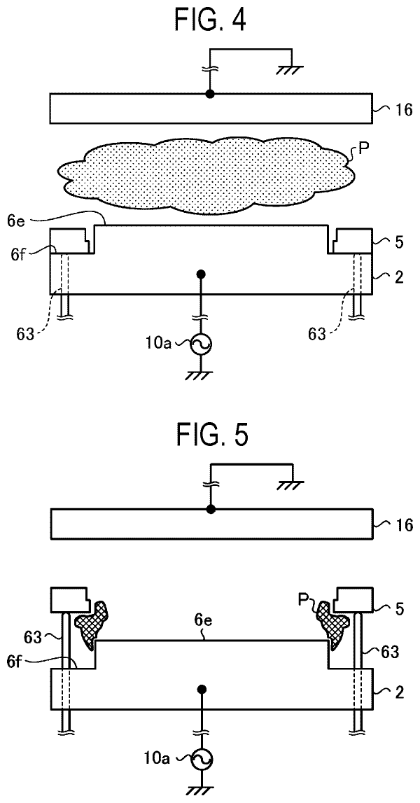

FIG. 4 is a diagram showing an example of a distribution of the plasma generated when the radio-frequency power is supplied in a state in which the edge ring 5 is placed on the second placement surface 6f. FIG. 5 is a diagram showing an example of the distribution of the plasma generated when the radio-frequency power is supplied in a state in which the edge ring 5 is spaced apart from the second placement surface 6f.

As shown in FIG. 4, when the radio-frequency power is supplied from the first RF power source 14a to the stage 2 in a state in which the edge ring 5 is placed on the second placement surface 6f, plasma P is evenly distributed in an in-plane direction of the stage 2 in the depressurized space between the stage 2 and the shower head 16.

Meanwhile, the present inventor(s) have found that, by separating the edge ring 5 and the second placement surface 6f from each other and setting such a separation distance appropriately, the plasma P may be unevenly distributed around a specific region above the stage 2 as shown in FIG. 5. Specifically, the present inventor(s) have found that, by separating the edge ring 5 and the second placement surface 6f from each other and setting the separation distance appropriately, the plasma P may be unevenly distributed around the region between the outer edge of the first placement surface 6e and the inner edge of the lower surface of the edge ring 5.

This mechanism may be explained, for example, as follows. That is, when the edge ring 5 and the second placement surface 6f are separated from each other, the depressurized space is also formed between the edge ring 5 and the second placement surface 6f. The depressurized space may be regarded as a capacitor provided on the radio-frequency power path extending from the first RF power source 14a to the ground connected to the shower head 16 via the stage 2. This capacitor becomes a portion of a composite impedance on the radio-frequency power path extending from the first RF power source 14a to the ground.

Here, the radio-frequency power path extending from the stage 2 to the shower head 16 is divided into above the first placement surface 6e and above the second placement surface 6f (hereinafter referred to as a “first placement surface path” and a “second placement surface path”). As shown in FIG. 4, when the edge ring 5 is placed on the second placement surface 6f, the composite impedance per unit area in the in-plane direction of the stage 2 remains almost the same in the first placement surface path and the second placement surface path. On the other hand, when the edge ring 5 and the second placement surface 6f are separated from each other as shown in FIG. 5, the second placement surface path is divided into parallel paths that include a path passing through the edge ring 5 and a path existing outside the edge ring 5 and not passing through the edge ring 5. The path passing through the edge ring 5 is a path passing through the capacitor formed in the depressurized space between the edge ring 5 and the second placement surface 6f, and the path not passing through the edge ring 5 is a path not passing through the capacitor.

Therefore, the composite impedance per unit area formed by the two parallel radio-frequency power paths above the second placement surface 6f is lower than the composite impedance per unit area formed above the first placement surface 6e.

The radio-frequency power flows intensively through the region above the second placement surface 6f where the composite impedance is relatively low. When the separation distance between the second placement surface 6f and the edge ring 5 is set appropriately, the radio-frequency power flows intensively through the region between the outer edge of the first placement surface 6e and inner edge of the lower surface of the edge ring 5 in the region above the second placement surface 6f. As a result, the density of plasma P in the region between the outer edge of the first placement surface 6e and the inner edge of the lower surface of the edge ring 5 becomes higher than the density of plasma P in other regions, so that ring-shaped plasma P is formed around the region between the outer edge of the first placement surface 6e and the inner edge of the lower surface of the edge ring 5.

In the cleaning process according to the first embodiment, by using the plasma P unevenly distributed around the region between the outer edge of the first placement surface 6e and the inner edge of the lower surface of the edge ring 5, the deposits may be removed intensively at a position where the density of the plasma is relatively high. That is, in the cleaning process according to the first embodiment, the plasma P may be concentrated around the region between the outer edge of the first placement surface 6e and the inner edge of the lower surface of the edge ring 5, thereby improving the ability to remove the deposits on the outer periphery of the stage 2, the inner periphery of the edge ring 5, and the lower surface of the edge ring 5. Therefore, the deposits accumulated on the outer periphery of the stage 2, the inner periphery of the edge ring 5, and the lower surface of the edge ring 5 may be reliably removed in a short period of time. In addition, since the density of the plasma P is relatively reduced in the regions other than the region between the outer edge of the first placement surface 6e and the inner edge of the lower surface of the edge ring 5, it is possible to prevent the portions corresponding to other regions of the stage 2 from being damaged by the plasma P. For example, since the density of the plasma P formed in the region above the first placement surface 6e is lower than the density of the plasma P formed in the region between the outer edge of the first placement surface 6e and the inner edge of the lower surface of the edge ring 5, it is possible to suppress damage to the first placement surface 6e.

As described above, in the cleaning process according to the first embodiment, the deposits accumulated on the outer periphery of the stage 2, the inner periphery of the edge ring 5, and the lower surface of the edge ring 5 may be removed while suppressing damage to the stage 2.

Further, in the cleaning process according to the first embodiment, the deposits may be efficiently removed without preparing electrodes having a special structure that locally generate plasma on the outer periphery of the stage 2, the inner periphery of the edge ring 5, and the lower surface of the edge ring 5.

Among the deposits accumulated on the outer periphery of the stage 2, the inner periphery of the edge ring 5, and the lower surface of the edge ring 5, the CF-based polymer deposits may be removed by the plasma of the oxygen-containing gas such as an O₂ gas or the like. Further, Si-based or metal-based deposits may be removed by plasma of a halogen-containing gas such as a CF₄ gas, an NF₃ gas, a Cl₂ gas, or an HBr gas. Further, mixed deposits of the CF-based polymer and at least one of the Si-based deposits and the metal-based deposits may be removed by plasma of a mixed gas of an oxygen-containing gas and a halogen-containing gas. Further, the CF-based polymer deposits may be removed using a hydrogen-containing gas such as a H₂ gas, or a nitrogen-containing gas such as N₂. In addition, a noble gas such as an argon gas or a helium gas may be added.

### (Removal Ability of the Cleaning Process)

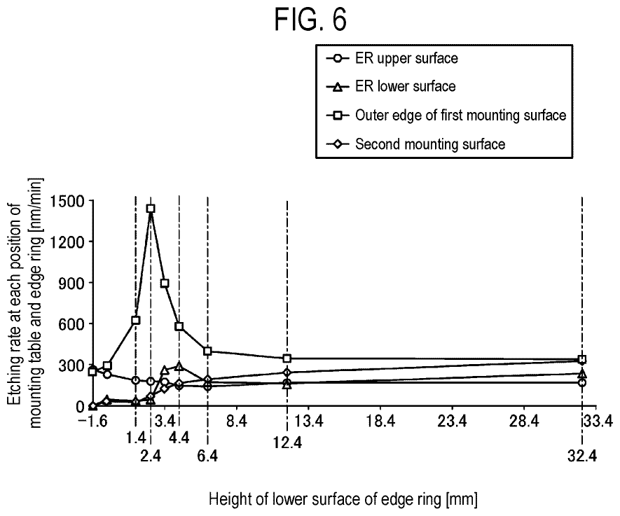

The present inventor(s) conducted an experiment to examine the removal ability of the cleaning process according to the first embodiment to remove the CF-based polymer deposit. In this experiment, as a substitute for the CF-based polymer deposit, test pieces coated with a resist film, which is an organic film similar to the CF-based polymer deposit, were installed at multiple positions on the stage 2 and the edge ring 5. In this experiment, an etching rate of the resist film at each position on the stage 2 and the edge ring 5 after the cleaning process according to the first embodiment has been performed was measured as the removal ability for the CF-based polymer deposit. Results of this experiment are shown in FIG. 6. FIG. 6 is a graph showing a relationship between a height of the lower surface of the edge ring 5 with respect to the first placement surface 6e when the edge ring 5 is separated from the second placement surface 6f and the etching rate of the resist film at each position on the stage 2 and the edge ring 5.

Processing conditions for the experimental results shown in FIG. 6 are as follows.
Internal pressure of processing container 10: 400 mT
Radio-frequency power (first RF power source 14a/second RF power source 14b): 600 W/0 W
DC voltage (variable DC power sensor 72): 0 V
Type and flow rate of gas: O₂ gas=700 sccm
Diameter of wafer W: 300 mm (no wafer W is accommodated in the processing container 10)
Processing time: 60 sec

Further, symbols in FIG. 6 indicate installation positions of the test pieces coated with the resist film. In the symbols indicated in FIG. 6, “ER upper surface” indicates the upper surface of the edge ring 5, and “ER lower surface” indicates the lower surface of the edge ring 5.

As shown in FIG. 6, when the height of the lower surface of the edge ring 5 is smaller than 1.4 mm, the etching rate at the outer edge of the first placement surface 6e and the lower surface of the edge ring 5 decreases. From this result, it may be seen that, when the height of the lower surface of the edge ring 5 is smaller than 1.4 mm, a difference between the density of the plasma generated around the region between the outer edge of the first placement surface 6e and the inner edge of the lower surface of the edge ring 5 and the density of the plasma generated in other regions is not so large.

Further, as shown in FIG. 6, when the height of the lower surface of the edge ring 5 is greater than 4.4 mm, the etching rate at the outer edge of the first placement surface 6e and the lower surface of the edge ring 5 decreases. From this result, it may be seen that, when the height of the lower surface of the edge ring 5 is greater than 4.4 mm, the difference between the density of the plasma generated around the region between the outer edge of the first placement surface 6e and the inner edge of the lower surface of the edge ring 5 and the density of the plasma generated in other regions is not so large.

From the above results, when the edge ring 5 is separated from the second placement surface 6f, it is preferable that the height of the lower surface of the edge ring 5 with respect to the first placement surface 6e is 1.4 mm or more and 4.4 mm or less. By setting the height of the lower surface of the edge ring 5 within this range, plasma may be appropriately unevenly distributed around the region between the outer edge of the first placement surface 6e and the inner edge of the lower surface of the edge ring 5. That is, while protecting the first placement surface 6e of the stage 2 from plasma, ring-shaped plasma may be generated around the region between the outer edge of the first placement surface 6e of the stage 2 and the inner edge of the lower surface of the edge ring 5.

Further, as shown in FIG. 6, the etching rate at the outer edge of the first placement surface 6e is maximum when the height of the lower surface of the edge ring 5 is 2.4 mm. From this result, it may be seen that, when the edge ring 5 is separated from the second placement surface 6f, the height of the lower surface of the edge ring 5 with respect to the first placement surface 6e is preferably 1.6 mm or more and 3.4 mm or less, more preferably 2.0 mm or more and 2.8 mm or less. By setting the height of the lower surface of the edge ring 5 within this range, the deposits accumulated on the outer periphery of the stage 2, the inner periphery of the edge ring 5, and the lower surface of the edge ring 5 may be reliably removed in a short period of time.

### Modification of the First Embodiment

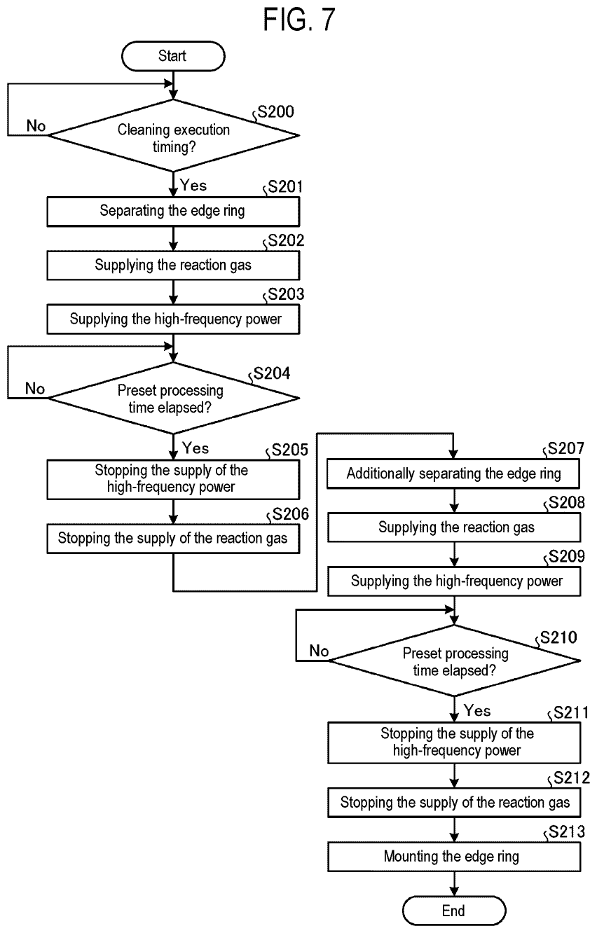

In the cleaning process described above, the PM 1 may further separate the edge ring 5 and the second placement surface 6f from each other after stopping the plasma generation, and then may generate plasma in the processing container 10 to clean the stage 2 and the edge ring 5. A flow of such a cleaning process will be described with reference to FIG. 7.

FIG. 7 is a flowchart showing an example of a flow of a cleaning process according to Modification 1 of the first embodiment. The cleaning process shown in FIG. 7 is implemented mainly by the PM 1 operating under the control of the controller 100. Further, the cleaning process shown in FIG. 7 is executed in a state where no wafer W is accommodated in the processing container 10. Steps S200 to S206 in FIG. 7 are similar to steps S100 to S106 shown in FIG. 3. Therefore, detailed descriptions thereof will be omitted herein.

When the supply of the radio-frequency power and the supply of the reaction gas are stopped to stop the plasma generation (S205 and S206), the edge ring 5 is further separated from the second placement surface 6f by further raising the lift pins 163 (S207). Information on the separation distance between the edge ring 5 and the second placement surface 6f is stored in, for example, the memory 103 in advance. The controller 100 raises the lift pins 163 according to the information stored in the memory 103. The separation distance in step S207 is larger than the separation distance in step S201.

Subsequently, after the interior of the processing container 10 is depressurized to a predetermined degree of vacuum by the first exhaust device 83, the reaction gas is supplied into the processing container 10 from the gas source 18 via the gas supply pipe 18a (S208).

Subsequently, the radio-frequency power is supplied to the stage 2, which is the lower electrode (S209). In step S209, the controller 100 controls the first RF power source 14a and the second RF power source 14b to generate the radio-frequency power, thereby supplying the radio-frequency power to the base 2a of the stage 2. Further, the controller 100 applies the DC power supplied from the variable DC power source 72 to the shower head 16 by turning on the on/off switch 73. As a result, plasma of the oxygen-containing gas is generated inside the processing container 10.

Subsequently, the controller 100 determines whether or not a preset processing time has elapsed since the start of the supply of the radio-frequency power in step S103 (S210). If the preset processing time has not elapsed (S210: No), the process of step S210 is executed again.

On the other hand, when it is determined that the preset processing time has elapsed (S210: Yes), the supply of the radio-frequency power to the stage 2 is stopped (S211). Further, the supply of the reaction gas into the processing container 10 is stopped (S212). As a result, the generation of the plasma of the oxygen-containing gas inside the processing container 10 is stopped.

After the reaction gas in the processing container 10 is exhausted, the edge ring 5 is placed on the second placement surface 6f by lowering the lift pins 163 (S213). This completes the cleaning method shown in this flowchart.

By cleaning the stage 2 and the edge ring 5 after further separating the edge ring 5 and the second placement surface 6f from each other in this way, the plasma spreads to the vicinity of the second placement surface 6f. As a result, the deposits accumulated on the second placement surface 6f may be removed.

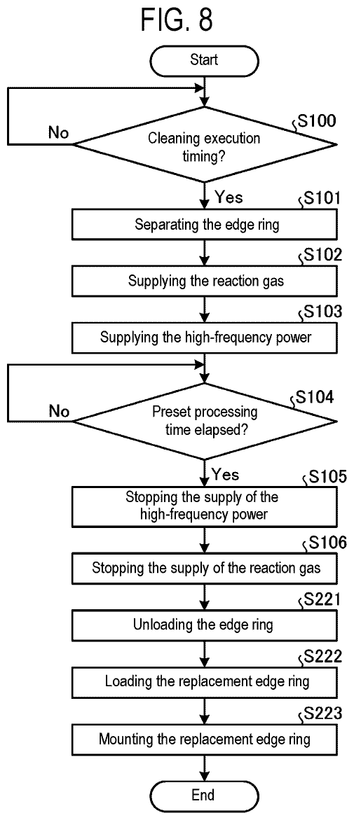

In the cleaning process shown in FIG. 7, instead of the process of step S213, processes of steps S221 to S223 shown in FIG. 8, which will be described later, may be performed. That is, after cleaning the stage 2 and the edge ring 5, the edge ring 5 may be replaced. Therefore, it is possible to suppress contamination caused when the deposits adhering to the edge ring 5 is carried out to the VTM 51.

Referring now to the experimental results shown in FIG. 6, the etching rate on the second placement surface 6f increases when the height of the lower surface of the edge ring 5 is 6.4 mm or more and 32.4 mm or less. On the other hand, the etching rate on the first placement surface 6e and the lower surface of the edge ring 5 is hardly changed and is kept at a constant value when the height of the lower surface of the edge ring 5 is 6.4 mm or more and 32.4 mm or more. From this result, when the edge ring 5 is separated from the second placement surface 6f, the height of the lower surface of the edge ring 5 with respect to the first placement surface 6e is preferably 6.4 mm or more and 32.4 mm or less, more preferably 12.4 mm or more and 32.4 mm or less. By setting the height of the lower surface of the edge ring 5 within this range, the density of plasma in the in-plane direction of the stage 2 is made even. Therefore, the deposits accumulated on the second placement surface 6f may be efficiently removed while suppressing damage to the first placement surface 6e and the lower surface of the edge ring 5.

Further, in the cleaning process described above, the PM 1 may replace the edge ring 5 after stopping the plasma generation. A flow of this cleaning process will be described with reference to FIG. 8.

FIG. 8 is a flowchart showing an example of a flow of a cleaning process according to Modification 2 of the first embodiment. The cleaning process shown in FIG. 8 is implemented mainly by the PM 1 operating under the control of the controller 100. Further, the cleaning process shown in FIG. 8 is executed in a state where no wafer W is accommodated in the processing container 10. Steps S100 to S106 shown in FIG. 8 are similar to steps S100 to S106 shown in FIG. 3. Therefore, detailed descriptions thereof will be omitted herein.

When the supply of the radio-frequency power and the supply of the reaction gas are stopped to stop the plasma generation (S105 and S106), the edge ring 5 is carried out (S221). That is, the edge ring 5 is carried out from the interior of the PM 1 by the transfer robot 510 and is returned to the accommodation device 52.

Subsequently, an edge ring for replacement 5 is carried into the PM 1 (S222). That is, the edge ring for replacement 5 is carried out from the accommodation device 52 by the transfer robot 510. The edge ring for replacement 5 is carried into the PM 1 and delivered to the lift pins 163. In step S222, the edge ring 5 that has been used but has a small amount of wear may be carried into the PM 1.

Subsequently, the lift pins 163 are lowered by driving the elevating mechanism 64, so that the edge ring for replacement 5 is placed on the second placement surface 6f (step S223).

In this way, since the edge ring 5 is transferred into the VTM 51 after cleaning the stage 2 and the edge ring 5, contamination caused when transferring the deposits adhering to the edge ring 5 into the VTM 51 may be suppressed.

### [Others]

In the first embodiment described above, there has been described the case where one stage 2 has the first placement surface 6e and the second placement surface 6f. However, the disclosed technique is not limited thereto. For example, the stage 2 may be divided into a first stage having the first placement surface 6e and a second stage having the second placement surface 6f. Further, when the stage 2 is divided into the first stage and the second stage, the second stage may be configured to include a base and an electrostatic chuck. In this case, the electrostatic chuck of the second stage has a disk shape with a flat upper surface, and the upper surface constitutes the second placement surface 6f on which the edge ring 5 is placed.

### [Effect]

As described above, the plasma processing apparatus (e.g., the PM 1) according to the first embodiment includes a stage (e.g., the stage 2), an elevating mechanism (e.g., the elevating mechanism 164), a radio-frequency power source (e.g., the first RF power source 14a), and a controller (e.g., the controller 100). The stage includes a first placement surface (e.g., the first placement surface 6e) on which a substrate (e.g., the wafer W) is placed, and a second placement surface (e.g., the second placement surface 6f) on which a ring member (e.g., the edge ring 5) surrounding the outer periphery of the first placement surface is placed. The elevating mechanism raises and lowers the ring member with respect to the second placement surface. The radio-frequency power source is connected to the stage. The controller is configured to execute a cleaning method including a separation operation and a removal operation. In the separation operation, the second placement surface and the ring member are separated from each other by the elevating mechanism. In the removal operation, after the separation operation, plasma is generated by supplying radio-frequency power from the radio-frequency power source to the stage to remove deposits accumulated on the stage and the ring member. In addition, in the separation operation, the separation distance between the second placement surface and the ring member is set such that the density of plasma generated in the region between the outer edge of the first placement surface and the inner edge of the lower surface of the ring member is higher than the density of plasma generated in other regions. As a result, according to the plasma processing apparatus of the first embodiment, it is possible to remove the deposits accumulated on the outer periphery of the stage, the inner periphery of the ring member, and the lower surface of the ring member while suppressing damage to the stage.

Further, in the separation operation, the height of the lower surface of the ring member with respect to the first placement surface may be 1.4 mm or more and 4.4 mm or less. As a result, according to the plasma processing apparatus of the first embodiment, while protecting the first placement surface of the stage from plasma, ring-shaped plasma may be generated around the region between the outer edge of the first placement surface of the stage and the inner edge of the lower surface of the ring member.

Further, in the separation operation, the height of the lower surface of the ring member with respect to the first placement surface is preferably 1.6 mm or more and 3.4 mm or less, more preferably 2.0 mm or more and 2.8 mm or less. As a result, according to the plasma processing apparatus of the first embodiment, the deposits accumulated on the outer periphery of the stage, the inner periphery of the ring member, and the lower surface of the ring member may be reliably removed in a short period of time.

Further, the cleaning method may include an additional separation operation and an additional removal operation. In the additional separation operation, after the removal operation, the second placement surface and the ring member may be further separated from each other by the elevating mechanism. In the additional removal operation, after the additional separation operation, plasma may be generated by supplying radio-frequency power from the radio-frequency power source to the stage to further remove the deposits accumulated on the stage and the ring member. Thus, according to the plasma processing apparatus of the first embodiment, the plasma spreads to the vicinity of the second placement surface. As a result, the deposits accumulated on the second placement surface may be removed.

Further, in the additional separation operation, the height of the lower surface of the ring member with respect to the first placement surface is preferably 6.4 mm or more and 32.4 mm or less, more preferably 12.4 mm or more and 32.4 mm or less. As a result, according to the plasma processing apparatus of the first embodiment, the density of plasma in the in-plane direction of the stage is made even. Therefore, the deposits accumulated on the second placement surface may be efficiently removed while suppressing damage to the first placement surface and the lower surface of the edge ring.

Further, the plasma processing apparatus according to the first embodiment may further include a processing container (e.g., the processing container 10) configured to accommodate the stage. The cleaning method may be executed in a state in which no substrate is accommodated in the processing container. As a result, according to the plasma processing apparatus of the first embodiment, the deposits accumulated on the outer periphery of the stage, the inner periphery of the ring member, and the lower surface of the ring member may be efficiently removed while exposing the first placement surface of the stage.

Further, in the removal operation, plasma of an oxygen-containing gas (e.g., an O₂ gas or a reaction gas obtained by adding a halogen gas the O₂ gas) may be generated. As a result, according to the plasma processing apparatus of the first embodiment, it is possible to suitably remove carbon-based deposits accumulated on the outer periphery of the stage, the inner periphery of the ring member, and the lower surface of the ring member.

Further, the ring member may be an edge ring. As a result, according to the plasma processing apparatus of the first embodiment, it is possible to remove the deposits accumulated on the outer periphery of the stage, the inner periphery of the edge ring, and the lower surface of the edge ring while suppressing damage to the stage.

### Second Embodiment

Next, a second embodiment will be described. A configuration of a substrate processing system 50 according to a second embodiment is similar to the configuration of the substrate processing system 50 shown in FIG. 1. Therefore, descriptions thereof will be omitted.

### [Configuration of Plasma Processing Apparatus]

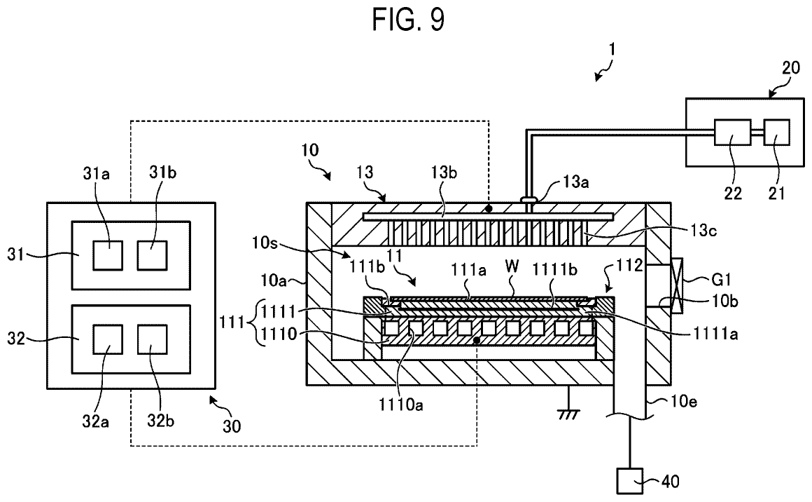

FIG. 9 is a schematic cross-sectional view showing an example of a structure of a PM 1 according to the second embodiment. The PM 1 is an example of a plasma processing apparatus.

In the present embodiment, the PM 1 is a capacitively coupled plasma processing apparatus. The PM 1 includes a plasma processing chamber 10, a gas supplier 20, a power source 30, and an exhaust system 40. Further, the PM 1 includes a substrate support 11 and a gas introducer. The plasma processing chamber 10 is an example of a processing container. The gas introducer is configured to introduce at least one processing gas into the plasma processing chamber 10. The gas introducer includes a shower head 13. The substrate support 11 is arranged inside the plasma processing chamber 10. The shower head 13 is arranged above the substrate support 11. In one embodiment, the shower head 13 forms at least a portion of the ceiling of the plasma processing chamber 10. The plasma processing chamber 10 has a plasma processing space 10s which is defined by the shower head 13, the sidewall 10a of the plasma processing chamber 10, and the substrate support 11. The plasma processing chamber 10 has at least one gas supply port for supplying at least one processing gas to the plasma processing space 10s therethrough, and at least one gas exhaust port for discharging the gas from the plasma processing space therethrough. The plasma processing chamber 10 is grounded. The shower head 13 and the substrate support 11 are electrically insulated from the housing of the plasma processing chamber 10. An opening 10b through which the wafer W is loaded into and unloaded from the plasma processing chamber 10 is formed in the sidewall 10a of the plasma processing chamber 10. The opening 10b is open and closed by a gate valve G1.

The substrate support 11 includes a main body portion 111 and a ring assembly 112. The main body portion 111 is an example of a stage. The main body portion 111 has a central region 111a for supporting the wafer W and an annular region 111b for supporting the ring assembly 112. The central region 111a is an example of the first placement surface, and the annular region 111b is an example of the second placement surface. The wafer W is an example of a substrate. The annular region 111b of the main body portion 111 surrounds the central region 111a of the main body portion 111 in a plan view. The wafer W is placed on the central region 111a of the main body portion 111, and the ring assembly 112 is placed on the annular region 111b of the main body portion 111 so as to surround the wafer W on the central region 111a of the main body portion 111. Therefore, the central region 111a is also called a substrate support surface for supporting the wafer W, and the annular region 111b is also called a ring support surface for supporting the ring assembly 112.

In one embodiment, the main body portion 111 includes a base 1110 and an electrostatic chuck 1111. The base 1110 includes a conductive member. The conductive member of the base 1110 may function as a lower electrode. The electrostatic chuck 1111 is arranged on the base 1110. The electrostatic chuck 1111 includes a ceramic member 1111a and a first electrode 1111b disposed inside the ceramic member 1111a. The ceramic member 1111a has a central region 111a. In one embodiment, the ceramic member 1111a also has an annular region 111b. Another member surrounding the electrostatic chuck 1111, such as an annular electrostatic chuck or an annular insulating member, may have the annular region 111b. In this case, the ring assembly 112 may be placed on the annular electrostatic chuck or the annular insulating member, or may be placed on both the electrostatic chuck 1111 and the annular insulating member. Further, at least one RF/DC electrode coupled to an RF (Radio Frequency) power source 31 and/or a DC (Direct Current) power source 32, which will be described later, may be arranged inside the ceramic member 1111a. In this case, the at least one RF/DC electrode functions as a lower electrode. The RF/DC electrode is also referred to as a bias electrode when the at least one RF/DC electrode is supplied with a bias RF signal and/or a DC signal as described below. The conductive member of the base 1110 and the at least one RF/DC electrode may function as a plurality of lower electrodes. In addition, the first electrode 1111b may function as a lower electrode. Therefore, the substrate support 11 includes at least one lower electrode.

The ring assembly 112 includes one or more annular members. In one embodiment, the one or more annular members include one or more edge rings and at least one cover ring. The edge ring is made of a conductive or insulating material, and the cover ring is made of an insulating material.

Further, the substrate support 11 may include a temperature control module configured to control the temperature of at least one of the electrostatic chuck 1111, the ring assembly 112, and the substrate to a target temperature. The temperature control module may include a heater, a heat transfer medium, a flow path 1110a, or a combination thereof. A heat transfer fluid such as brine or gas flows through the flow path 1110a. In one embodiment, a flow path 1110a is formed inside the base 1110, and one or more heaters are disposed inside a ceramic member 1111a of the electrostatic chuck 1111. Further, the substrate support 11 may include a heat transfer gas supplier configured to supply the heat transfer gas to a gap between the back surface of the wafer W and the central region 111a. Although not shown in FIG. 2, the substrate support 11 includes the heat transfer gas supplier configured to supply the heat transfer gas to the gap between the back surface of the edge ring and the annular region 111b. Further, although not shown in FIG. 2, the substrate support 11 is provided with a plurality of lift pins.

The shower head 13 is configured to introduce at least one processing gas from the gas supplier 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s via the plurality of gas introduction ports 13c. The shower head 13 also includes at least one upper electrode. In addition to the shower head 13, the gas introducer may include one or more side gas injectors (SGI) attached to one or more openings formed in the sidewall 10a.

The gas supplier 20 may include at least one gas source 21 and at least one flow rate controller 22. In one embodiment, the gas supplier 20 is configured to supply at least one processing gas from the corresponding gas source 21 to the shower head 13 via the corresponding flow rate controller 22. Each flow controller 22 may include, for example, a mass flow controller or a pressure-controlled flow rate controller. Further, the gas supplier 20 may include one or more flow rate modulation devices that modulate or pulse the flow rate of at least one processing gas.

The power source 30 includes an RF power source 31 coupled to the plasma processing chamber 10 via at least one impedance matching circuit. The RF power source 31 is configured to supply at least one RF signal (RF power) to at least one lower electrode and/or at least one upper electrode. Thus, plasma is formed from at least one processing gas supplied to the plasma processing space 10s. Accordingly, the RF power source 31 may function as at least a portion of a plasma generator configured to generate plasma from one or more processing gases in the plasma processing chamber 10. Further, by supplying a bias RF signal to at least one lower electrode, a bias potential is generated in the wafer W, and ion components in the formed plasma may be drawn into the wafer W.

In one embodiment, the RF power source 31 includes a first RF generator 31a and a second RF generator 31b. The first RF generator 31a is coupled to at least one lower electrode and/or at least one upper electrode via at least one impedance matching circuit, and is configured to generate a source RF signal (source RF power) for plasma generation. In one embodiment, the source RF signal has a frequency in the range of 10 MHz to 150 MHz. In one embodiment, the first RF generator 31a may be configured to generate multiple source RF signals having different frequencies. The one or more source RF signals thus generated are provided to at least one lower electrode and/or at least one upper electrode.

The second RF generator 31b is coupled to at least one lower electrode via at least one impedance matching circuit, and is configured to generate a bias RF signal (bias RF power). A frequency of the bias RF signal may be the same as or different from that of the source RF signal. In one embodiment, the bias RF signal has a lower frequency than the frequency of the source RF signal. In one embodiment, the bias RF signal has a frequency in the range of 100 kHz to 60 MHz. In one embodiment, the second RF generator 31b may be configured to generate multiple bias RF signals having different frequencies. The one or more bias RF signals thus generated are provided to at least one lower electrode. Further, in various embodiments, at least one of the source RF signal and the bias RF signal may be pulsed.

The power source 30 may also include a DC power source 32 coupled to the plasma processing chamber 10. The DC power source 32 includes a first DC generator 32a and a second DC generator 32b. In one embodiment, the first DC generator 32a is connected to at least one lower electrode and configured to generate a first DC signal. The first bias DC signal thus generated is applied to the at least one lower electrode. In one embodiment, the second DC generator 32b is connected to the at least one upper electrode and configured to generate a second DC signal. The second DC signal thus generated is applied to the at least one upper electrode.

In various embodiments, at least one of the first and second DC signals may be pulsed. In this case, a sequence of voltage pulses is applied to at least one lower electrode and/or at least one upper electrode. The voltage pulse may have a rectangular pulse waveform, a trapezoidal pulse waveform, a triangular pulse waveform, or a combination thereof. In one embodiment, a waveform generator for generating a sequence of voltage pulses from a DC signal is connected between the first DC generator 32a and the at least one lower electrode. Therefore, the first DC generator 32a and the waveform generator constitute a voltage pulse generator. When the second DC generator 32b and the waveform generator constitute a voltage pulse generator, the voltage pulse generator is connected to at least one upper electrode. The voltage pulse may have positive polarity or negative polarity. Further, the sequence of voltage pulses may include one or more positive voltage pulses and one or more negative voltage pulses within one cycle. The first and second DC generators 32a and 32b may be provided in addition to the RF power source 31, or the first DC generator 32a may be provided in place of the second RF generator 31b.

The exhaust system 40 may be connected to, for example, a gas exhaust port 10e provided at the bottom of the plasma processing chamber 10. The exhaust system 40 may include a pressure regulation valve and a vacuum pump. An internal pressure of the plasma processing space 10s is regulated by the pressure regulation valve. The vacuum pump may include a turbomolecular pump, a dry pump, or a combination thereof.

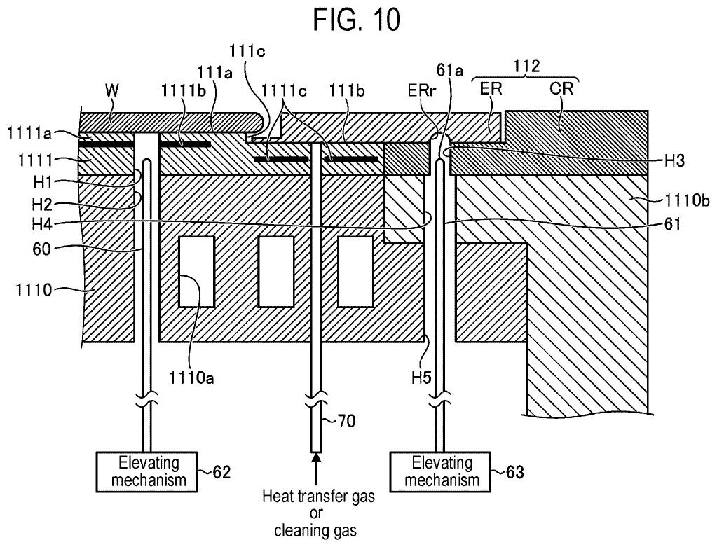

FIG. 10 is an enlarged cross-sectional view showing an example of a structure near the edge of the electrostatic chuck 1111. The base 1110 is supported by an annular insulating member 1110b. The ring assembly 112 includes an edge ring ER and a cover ring CR. A portion of the edge ring ER is arranged above the annular region 111b. Further, the outer periphery of the edge ring ER and the inner periphery of the cover ring CR overlap each other when viewed from above. The edge ring ER is made of a conductive material such as silicon or silicon carbide. The cover ring CR is arranged on the insulating member 1110b. The cover ring CR is made of an insulating material such as quartz or the like, and is configured to protect the upper surface of the insulating member 1110b from plasma. The edge ring ER may be made of an insulating material such as quartz or the like. Further, the cover ring CR may be made of a conductive material such as silicon or silicon carbide.

In the electrostatic chuck 1111, a first electrode 1111b is embedded below the central region 111a, and a second electrode 1111c is embedded below the annular region 111b. The first electrode 1111b electrostatically attracts the wafer W or the dummy wafer to the central region 111a by virtue of an electrostatic force generated according to the applied voltage. The second electrode 1111c electrostatically attracts the edge ring ER to the annular region 111b by virtue of the electrostatic force generated according to the applied voltage. In the example of FIG. 10, the first electrode 1111b is a unipolar electrode. However, as another example, the first electrode 1111b may be a bipolar electrode. Further, in the example of FIG. 10, the second electrode 1111c is a bipolar electrode. However, as another example, the second electrode 1111c may be a unipolar electrode.

Below the central region 111a, the electrostatic chuck 1111 has through-holes H1 formed therein, and the base 1110 has through-holes H2 formed therein. Lift pins 60 are inserted into the through-holes H1 and the through-holes H2. The lift pins 60 are raised and lowered by an elevating mechanism 62. By raising and lowering the lift pins 60, the wafer W or the dummy wafer placed on the central region 111a may be raised and lowered. In the present embodiment, three lift pins 60 are provided in the central region 111a.

Below the region where the edge ring ER and the cover ring CR overlap each other when viewed from above, through-holes H3 are formed in the cover ring CR, through-holes H4 are formed in the insulating member 1110b, and through-holes H5 are formed in the base 1110. Lift pins 61 are inserted into the through-holes H3 to H5. The lift pins 61 are raised and lowered by an elevating mechanism 63. By raising and lowering the lift pins 61, the edge ring ER above the cover ring CR may be raised and lowered. In the present embodiment, three lift pins 61 are provided in the annular region 111b. Recesses ERr are formed on the lower surface of the edge ring ER at positions corresponding to the positions of the through-holes H3. As the lift pins 61 are raised, tips 61a of the lift pins 61 come into contact with the recesses ERr. Thus, the lift pins 61 may stably support the edge ring ER by the tips 61a thereof.

Below the annular region 111b, a gas supply pipe 70 is provided in the electrostatic chuck 1111 and the base 1110 so as to penetrate through the electrostatic chuck 1111 and the base 1110. The gas supply pipe 70, which is connected to a gas source (not shown), supplies a heat transfer gas such as a helium gas to a gap between the back surface of the edge ring ER and the annular region 111b. The gas supply pipe 70 is an example of a heat transfer gas supplier. The gas supply pipe 70 may be connected to another gas source (not shown) via a branch pipe (not shown) to supply a cleaning gas instead of the heat transfer gas to the gap between the back surface of the edge ring ER and the annular region 111b.

### [One Example of the Flow of the Cleaning Process According to the Second Embodiment]

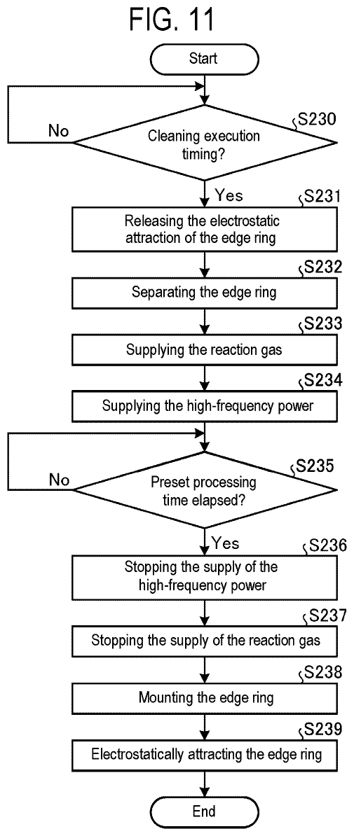

Next, the flow of the cleaning process executed by the PM 1 according to the second embodiment will be described with reference to FIG. 11. FIG. 11 is a flowchart showing one example of the flow of the cleaning process according to the second embodiment. The respective steps illustrated in FIG. 11 are implemented by controlling each part of the substrate processing system 50 with the controller 9. Further, the cleaning process illustrated in FIG. 11 is executed in a state where no wafer W is accommodated in the plasma processing chamber 10.

First, the controller 9 determines whether or not a timing to execute the cleaning process has arrived (S230). The timing to execute the cleaning process may be, for example, a timing at which the execution of a process such as plasma etching is completed for a predetermined number of wafers W. When it is determined that the timing to execute the cleaning process has not arrived (S230: No), the process of step S230 is executed again.

When it is determined that the timing to execute the cleaning process has arrived (S230: Yes), the electrostatic attraction of the edge ring ER to the annular region 111b is released by stopping the application of the voltage to the second electrode 1111c (S231).

Subsequently, the edge ring ER is separated from the annular region 111b by raising (pining-up) the lift pins 61 through the operation of the elevating mechanism 63 (S232). Information on the separation distance between the edge ring ER and the annular region 111b is stored, for example, in the memory 9a2 in advance, and the controller 9 raises the lift pins 61 according to the information stored in the memory 9a2.

Subsequently, after the interior of the plasma processing chamber 10 is depressurized to a predetermined degree of vacuum by the exhaust system 40, a reaction gas (cleaning gas) is supplied into the plasma processing chamber 10 from the gas supplier 20 (S233).

The cleaning gas supplied into the plasma processing chamber 10 in step S233 includes, for example, at least one selected from the group consisting of an O₂ gas, an O₃ gas, a CO gas, a CO₂ gas, a COS gas, an N₂ gas and an H₂ gas. The cleaning gas may further include a halogen-containing gas such as a CF₄ gas, an NF₃ gas, an SF₆ gas, a Cl₂ gas or an HBr gas.

In step S233, the cleaning gas may be supplied from the gas supplier 20 into the plasma processing chamber 10. Instead of the heat transfer gas, the cleaning gas may be supplied from the gas supply pipe 70 into the plasma processing chamber 10. This increases a concentration of the plasma above the annular region 111b, which making it possible to efficiently remove the deposits accumulated on the outer periphery of the electrostatic chuck 1111, the inner periphery of the edge ring ER, and the lower surface of the edge ring ER. Further, the deposits adhering to the interior of the gas supply pipe 70 may also be removed.

The cleaning gas supplied into the plasma processing chamber 10 from the gas supply pipe 70 may further include a halogen-containing gas such as a CF₄ gas, an NF₃ gas, an SF₆ gas, a Cl₂ gas or an HBr gas. This increases a concentration of the plasma above the annular region 111b, which making it possible to efficiently remove the deposits containing silicon or metal. Further, the deposits adhering to the interior of the gas supply pipe 70 and containing silicon or metal may also be removed.

Subsequently, radio-frequency power is supplied to the base 1110, which is the lower electrode (S234). In step S234, the controller 9 controls the RF power source 31 to generate radio-frequency power, thereby supplying the radio-frequency power to the conductive member of the base 1110. Further, the controller 9 controls the DC power source 32 to apply DC power to the shower head 13. As a result, plasma of the cleaning gas is generated inside the plasma processing chamber 10, and the interior of the plasma processing chamber 10 is cleaned by the plasma generated from the cleaning gas.

Subsequently, the controller 9 determines whether or not a preset processing time (cleaning time) has elapsed since the start of the supply of the radio-frequency power in step S234 (S235). When it is determined that the preset processing time has not elapsed (S235: No), the process of step S235 is executed again.

On the other hand, when it is determined that the preset processing time has elapsed (S235: Yes), the supply of the radio-frequency power to the base 1110 is stopped (S236). Further, the supply of the reaction gas (cleaning gas) into the plasma processing chamber 10 is stopped (S237). As a result, the generation of the plasma of the cleaning gas in the plasma processing chamber 10 is stopped.

After the reaction gas in the plasma processing chamber 10 is exhausted, the elevating mechanism 63 is driven to lower the lift pins 61 and place the edge ring ER on the annular region 111b.

Subsequently, the edge ring ER is electrostatically attracted to the annular region 111b (step S239). In step S239, the edge ring ER is attracted and held on the annular region 111b by the electrostatic force generated according to the voltage applied to the second electrode 1111c. This completes the cleaning method shown in this flowchart.

In steps S232 to S237 described above, a density of the plasma generated in the region between the outer edge of the central region 111a and the inner edge of the lower surface of the edge ring ER is set to be higher than that of the plasma generated in other regions. This makes it possible to efficiently remove the deposits accumulated on the outer periphery of the main body portion 111, the inner periphery of the edge ring ER, and the lower surface of the edge ring ER while suppressing damage to the main body portion 111.

Further, in steps S232 to S237 described above, the cleaning may be executed while a height position of the edge ring ER is maintained such that the lower surface of the edge ring ER is higher than the upper surface of the cover ring CR. Thus, the deposits volatilized by the plasma may be smoothly exhausted from the gap between the edge ring ER and the cover ring CR, and the efficiency of removing the deposits may be improved.

### Modifications of the Second Embodiment

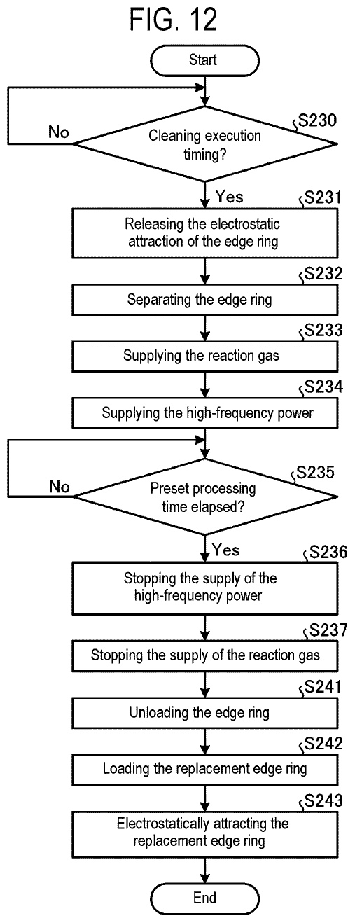

In the cleaning process described above, the PM 1 may replace the edge ring ER after stopping the plasma generation. A flow of this cleaning process will be described with reference to FIG. 12.

FIG. 12 is a flowchart showing an example of the flow of the cleaning process according to Modification 1 of the second embodiment. The cleaning process illustrated in FIG. 12 is implemented mainly by operating the PM 1 under the control of the controller 9. Further, the cleaning process illustrated in FIG. 12 is performed in a state where no wafer W is accommodated in the plasma processing chamber 10. Steps S230 to S237 in FIG. 12 are the same as steps S230 to S237 shown in FIG. 11. Therefore, detailed descriptions thereof will be omitted herein.

When the supply of the radio-frequency power and the supply of the reaction gas are stopped and the generation of the plasma is stopped (S236 and S237), the edge ring ER is carried out (S241). That is, the edge ring ER is carried out from the interior of the PM 1 by the transfer robot 510 and is returned to the accommodation device 52.

Subsequently, an edge ring for replacement ER is carried into the PM 1 (S242). That is, the edge ring for replacement ER is carried out from the interior of the accommodation device 52 by the transfer robot 510. The edge ring for replacement ER is carried into the PM 1 and delivered to the lift pins 61. In step S242, an edge ring ER that has been used but has a small amount of wear may be carried into the PM 1.

Subsequently, the lift pins 61 are lowered by driving the elevating mechanism 63, so that the edge ring for replacement ER is placed on the annular region 111b and is electrostatically attracted to the annular region 111b (step S243). That is, the edge ring ER is attracted and held on the annular region 111b by the electrostatic force generated according to the voltage applied to the second electrode 1111c.

In this manner, in Modification 1, by replacing the edge ring ER after cleaning the stage and the edge ring ER, it is possible to suppress contamination of the replaced edge ring ER. In addition, in Modification 1, by carrying out the edge ring ER to the VTM 51 after cleaning the stage and the edge ring ER, it is possible to suppress contamination caused when carrying out the deposits adhering to the edge ring ER to the VTM 51.

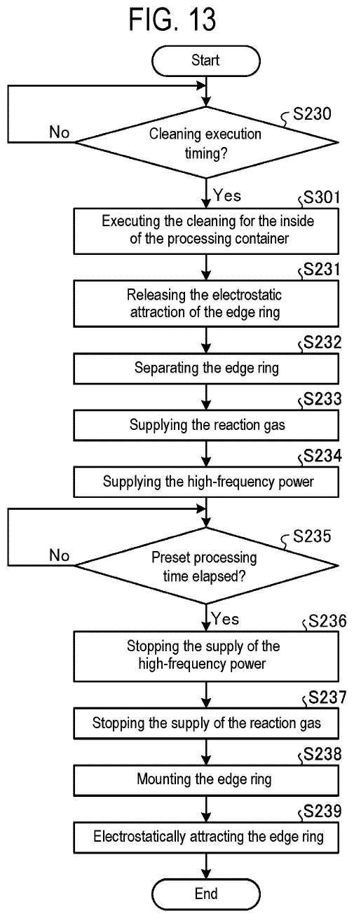

FIG. 13 is a flowchart showing an example of a flow of a cleaning process according to Modification 2 of the second embodiment. The cleaning process illustrated in FIG. 13 is implemented mainly by the PM 1 operating under the control of the controller 9. Further, the cleaning process illustrated in FIG. 13 is performed in a state where no wafer W is accommodated in the plasma processing chamber 10. Steps S230 to S239 in FIG. 13 are the same as steps S230 to S239 shown in FIG. 11. Therefore, detailed descriptions thereof will be omitted herein.

In the cleaning process shown in FIG. 13, when it is determined that the timing to execute the cleaning process has arrived (S230: Yes), the cleaning for the interior of the plasma processing chamber 10 is executed before the cleaning in steps S231 to S239 is executed (S301). In step S301, the cleaning for the interior of the plasma processing chamber 10 is executed with no wafer W placed in the central region 111a. In step S301, a reaction gas (cleaning gas) is supplied from the gas supplier 20 into the plasma processing chamber 10, and radio-frequency power is supplied to the base 1110. As a result, in step S301, plasma of the cleaning gas is generated inside the plasma processing chamber 10 so that the interior of the plasma processing chamber 10 is cleaned by the plasma generated from the cleaning gas.

The cleaning gas supplied into the plasma processing chamber 10 in step S301 may be the same as or different from the cleaning gas supplied into the plasma processing chamber 10 in step S233. The cleaning executed in step S301 is an example of a first cleaning.

When the cleaning in step S301 is completed, cleaning in steps S231 to S239 is executed. The cleaning executed in steps S231 to S239 is an example of a second cleaning.

As described above, in Modification 2, the interior of the plasma processing chamber 10 is cleaned before the cleaning in steps S231 to S239. This makes it possible to more efficiently remove the deposits accumulated on the outer periphery of the electrostatic chuck 1111, the inner periphery of the edge ring ER, and the lower surface of the edge ring ER while suppressing damage to the electrostatic chuck 1111.

In the cleaning process shown in FIG. 13, instead of the processes of steps S238 and S239, the processes of steps S221 to S223 shown in FIG. 8 may be performed. After the process of step S223, the edge ring for replacement ER may be electrostatically attracted to the annular region 111b.

Further, step S301 and step S231 may be executed at the same timing. That is, the electrostatic attraction of the edge ring ER to the annular region 111b may be released in parallel with the cleaning of the plasma processing chamber 10 in a state in which the wafer W is not placed on the central region 111a. In this case, for example, the electrostatic attraction of the edge ring ER to the annular region 111b may be released by applying a voltage of opposite polarity to the voltage for electrostatic attraction to the second electrode 1111c (see FIG. 10) in parallel with the cleaning for the interior of the plasma processing chamber 10.

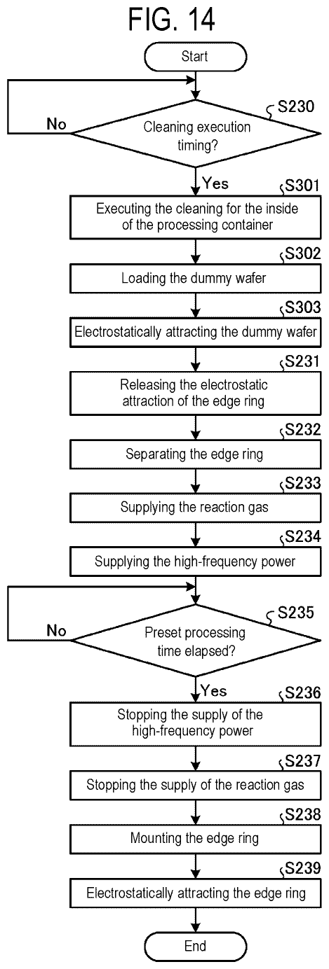

FIG. 14 is a flowchart showing an example of a flow of a cleaning process according to Modification 3 of the second embodiment. The cleaning process illustrated in FIG. 14 is implemented mainly by the PM 1 operating under the control of the controller 9. Steps S230 to S239 shown in FIG. 14 are the same as steps S230 to S239 shown in FIG. 11. Therefore, detailed descriptions thereof will be omitted herein. Further, since step S301 shown in FIG. 14 is the same as step S301 shown in FIG. 13, detailed descriptions thereof will be omitted herein.

In the cleaning process shown in FIG. 14, when the cleaning in step S301 is completed, a dummy wafer is loaded into the plasma processing chamber 10 (S302). In step S302, the gate valve G4 is open, and the dummy wafer is carried out from the accommodation device 52 by the transfer robot 510. Then, the gate valve G1 is open, and the dummy wafer is loaded into the PM 1 and delivered to the lift pins 60. Then, the lift pins 60 are lowered by driving the elevating mechanism 62, so that the dummy wafer is placed on the central region 111a of the electrostatic chuck 1111. In this case, a diameter of the dummy wafer placed on the central region 111a in step S302 is smaller than an inner diameter of the edge ring ER. Therefore, even when the dummy wafer is placed on the central region 111a, the edge ring ER may be separated from the annular region 111b without interference between the dummy wafer and the edge ring ER.

Subsequently, the dummy wafer is electrostatically attracted to the central region 111a (S303). Then, the cleaning (second cleaning) in steps S231 to S239 is executed. In steps S231 to S239, the interior of the plasma processing chamber 10 is cleaned with the dummy wafer placed on the central region 111a.

Processing conditions for the cleaning in steps S231 to S239 may be such that at least one parameter is changed from processing conditions for the cleaning in step S301. The processing conditions for the cleaning in steps S231 to S239 and the cleaning in step S301 include, for example, at least one parameter selected from the group of parameters consisting of a gas type, a gas flow rate ratio, a gas flow rate, a pressure, bias power, plasma generation power, a temperature of the electrostatic chuck 1111 and a cleaning time.

In steps S231 to S239, the cleaning may be executed under conditions that provide higher cleaning performance than the cleaning executed in step S301. Thus, it is possible to efficiently remove the deposits adhering to the used edge ring ER, and it is possible to suppress the deposits from falling during the process of transferring the used edge ring ER. For example, the plasma generation power supplied to the upper electrode and/or the lower electrode in the cleaning in steps S231 to S239 may be greater than the plasma generation power supplied in the first cleaning. Further, the cleaning in steps S231 to S239 may be executed with a higher bias power than in the cleaning in step S301. Alternatively, the bias power may not be supplied in the cleaning in step S301, but the bias power may be supplied in the cleaning in steps S231 to S239. Further, the cleaning in steps S231 to S239 may be executed at a higher pressure than in the cleaning in step S301. Further, the cleaning in steps S231 to S239 may be executed with a higher pressure and larger bias power than in the cleaning in step S301. Further, the temperature of the electrostatic chuck 1111 during the cleaning in steps S231 to S239 may be higher than the temperature of the electrostatic chuck 1111 during the cleaning in step S301. The temperature of the electrostatic chuck 1111 may be controlled, for example, by controlling a temperature of a temperature-control medium (heat transfer fluid) flowing through the flow path 1110a, and/or by controlling a heater (not shown) in the electrostatic chuck 1111. Further, the temperature control of the electrostatic chuck 1111 may be started after step S301 comes to an end. Further, the cleaning in steps S231 to S239 may be executed for a longer time than in the cleaning in step S301. Further, in steps S231 to S239, the cleaning may be executed using a gas (e.g., a halogen-containing gas) that is more corrosive than the gas used in the cleaning executed in step S301. Further, a highly corrosive gas (e.g., a halogen-containing gas) may be used for the cleaning in step S301. In this case, a flow rate of the highly corrosive gas used in the cleaning in steps S231 to S239 may be greater than that of the highly corrosive gas used in the cleaning in step S301.

As described above, in Modification 3, the interior of the plasma processing chamber 10 is cleaned before the cleaning in steps S231 to S239. This makes it possible to more efficiently remove the deposits accumulated on the outer periphery of the electrostatic chuck 1111, the inner periphery of the edge ring ER, and the lower surface of the edge ring ER while suppressing damage to the electrostatic chuck 1111.

Further, in Modification 3, the cleaning in steps S231 to S239 is executed with the dummy wafer placed on the central region 111a. Thus, even if the interior of the plasma processing chamber 10 is cleaned under the conditions that provide high cleaning performance, it is possible to reduce damage to the central region 111a.

In the cleaning process shown in FIG. 14, the processes of steps S221 to S223 shown in FIG. 8 may be performed instead of the processes of steps S238 and S239, and the edge ring for replacement ER may be electrostatically attracted to the annular region 111b after the process of step S223.

Further, step S303 and step S231 may be executed at the same timing. That is, the electrostatic attraction of the edge ring ER to the annular region 111b may be released in parallel with the electrostatic attraction of the dummy wafer to the central region 111a. In this case, for example, after the dummy wafer is placed on the central region 111a, a gas such as a nitrogen gas or an oxygen gas may be supplied into the plasma processing chamber 10 to control the internal pressure of the plasma processing chamber 10 to a predetermined pressure, and radio-frequency power may be supplied to the plasma processing chamber 10 to generate plasma. In this state, a voltage may be applied to the first electrode 1111b (see FIG. 10) to electrostatically attract the dummy wafer to the central region 111a, and a voltage of opposite polarity to the voltage for electrostatic attraction may be applied to the second electrode 1111c to release the electrostatic attraction of the edge ring ER to the annular region 111b. Although the plasma is generated, an inert gas (nitrogen, or the like) may be supplied into the plasma processing chamber 10 to control the internal pressure of the plasma processing chamber 10 to a predetermined pressure (without generating plasma). In this state, the electrostatic attraction of the dummy wafer and the release of the electrostatic attraction of the edge ring may be performed.

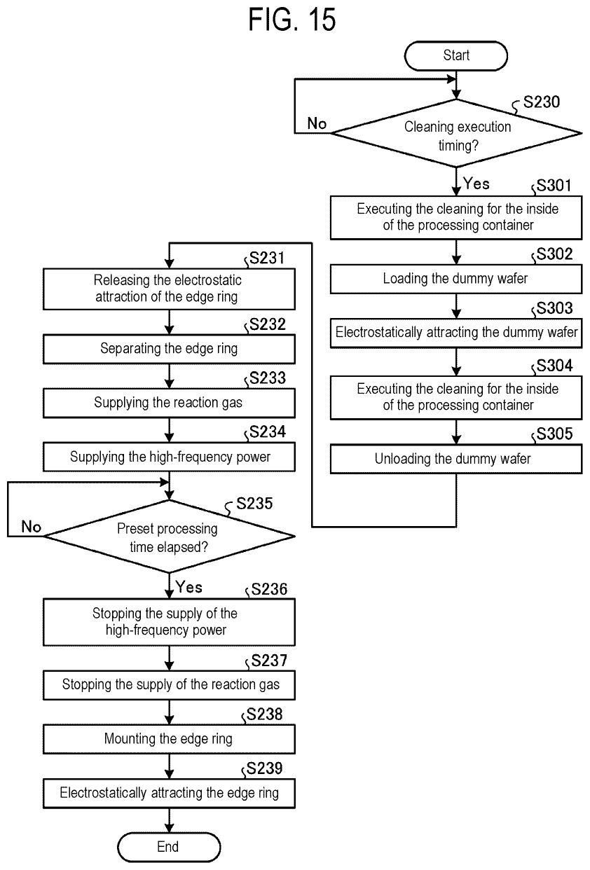

FIG. 15 is a flowchart showing an example of a flow of a cleaning process according to Modification 4 of the second embodiment. The cleaning process illustrated in FIG. 15 is implemented mainly by the PM 1 operating under the control of the controller 9. Steps S230 to S239 shown in FIG. 15 are the same as steps S230 to S239 shown in FIG. 11. Therefore, detailed descriptions thereof will be omitted herein. Further, since steps S301 to S303 shown in FIG. 15 are the same as steps S301 to S303 shown in FIG. 14, detailed descriptions thereof will be omitted herein.

In the cleaning process shown in FIG. 15, when the dummy wafer is electrostatically attracted to the central region 111a (S303), the interior of the plasma processing chamber 10 is cleaned (S304). In step S304, the interior of the plasma processing chamber 10 is cleaned with the dummy wafer placed on the central region 111a. In this case, the diameter of the dummy wafer placed on the central region 111a may be the same as the diameter of the wafer W, or may be smaller than the diameter of the wafer W and the inner diameter of the edge ring ER. In step S304, a reaction gas (cleaning gas) is supplied from the gas supplier 20 into the plasma processing chamber 10, and radio-frequency power is supplied to the base 1110. As a result, in step S304, plasma of the cleaning gas is generated inside the plasma processing chamber 10, and the interior of the plasma processing chamber 10 is cleaned by the plasma generated from the cleaning gas.

The cleaning gas supplied into the plasma processing chamber 10 in step S304 may be the same as or different from the cleaning gas supplied into the plasma processing chamber 10 in step S233. The cleaning executed in step S304 is an example of a first cleaning.

When the cleaning in step S304 is completed, the dummy wafer is unloaded (S305). In step S305, the elevating mechanism 62 is driven to raise the lift pins 60, thereby lifting the dummy wafer. Then, the gate valve G1 is open, and the dummy wafer is unloaded from the PM 1 by the transfer robot 510.

Subsequently, cleaning in steps S231 to S239 is executed. The cleaning executed in steps S231 to S239 is an example of a second cleaning.

As described above, in Modification 4, the interior of the plasma processing chamber 10 is cleaned before the cleaning in steps S231 to S239. This makes it possible to more efficiently remove the deposits accumulated on the outer periphery of the electrostatic chuck 1111, the inner periphery of the edge ring ER, and the lower surface of the edge ring ER while suppressing damage to the electrostatic chuck 1111.

In the cleaning process shown in FIG. 15, the processes of steps S221 to S223 shown in FIG. 8 may be performed instead of the processes of steps S238 and S239. After the process of step S223, the edge ring for replacement ER may be electrostatically attracted to the annular region 111b.

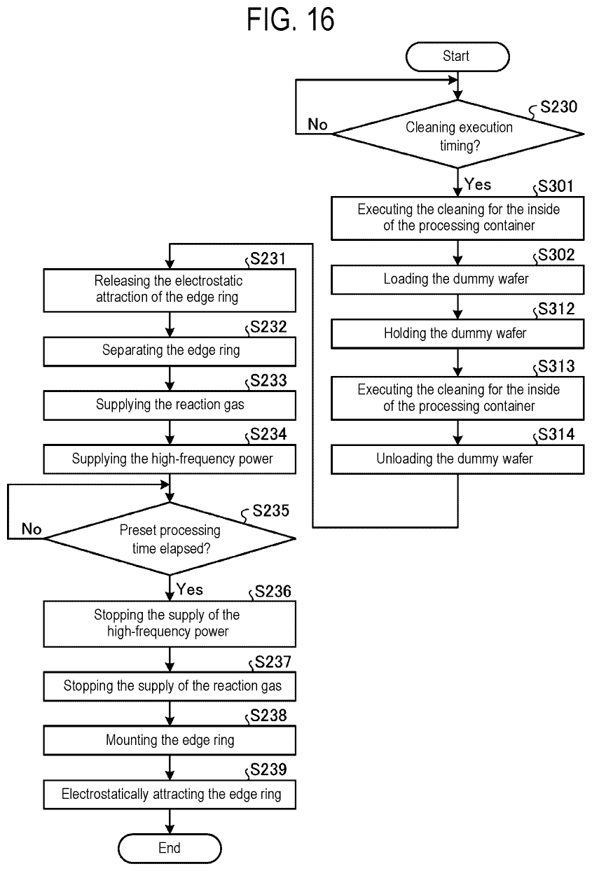

FIG. 16 is a flowchart showing an example of a flow of a cleaning process according to Modification 5 of the second embodiment. The cleaning process illustrated in FIG. 16 is implemented mainly by the PM 1 operating under the control of the controller 9. Steps S230 to S239 shown in FIG. 16 are the same as steps S230 to S239 shown in FIG. 11. Therefore, detailed descriptions thereof will be omitted herein. Further, since steps S301 to S302 shown in FIG. 16 are the same as steps S301 to S302 shown in FIG. 15, detailed descriptions thereof will be omitted herein.

In the cleaning process shown in FIG. 16, the following process is performed after the dummy wafer is loaded into the plasma processing chamber 10 (S302). That is, by raising (pining-up) the lift pins 60 by driving the elevating mechanism 62, the dummy wafer is held at a position spaced apart by a predetermined distance (e.g., 1 to 5 mm) from the central region 111a (S312). Information on a separation distance between the dummy wafer and the central region 111a is stored, for example, in the memory 9a2 in advance. The controller 9 raises the lift pins 60 according to the information stored in the memory 9a2.

Subsequently, cleaning for the interior of the plasma processing chamber 10 is executed (S313). In step S313, the interior of the plasma processing chamber 10 is cleaned with the dummy wafer separated from the central region 111a. In step S313, a reaction gas (cleaning gas) is supplied from the gas supplier 20 into the plasma processing chamber 10, and radio-frequency power is supplied to the base 1110. Thus, in step S313, plasma of the cleaning gas is generated inside the plasma processing chamber 10, and the interior of the plasma processing chamber 10 is cleaned by the plasma generated from the cleaning gas. The cleaning executed in step S313 is an example of a third cleaning.

The cleaning gas supplied into the plasma processing chamber 10 in step S313 may be the same as or different from the cleaning gas supplied into the plasma processing chamber 10 in step S233.

When the cleaning in step S313 is completed, the dummy wafer is unloaded (S314). In step S314, the elevating mechanism 62 is driven to raise the lift pins 60, thereby lifting the dummy wafer. Then, the gate valve G1 is open, and the dummy wafer is unloaded from the PM 1 by the transfer robot 510.

Subsequently, cleaning in steps S231 to S239 is executed. The cleaning executed in steps S231 to S239 is an example of a second cleaning.

As described above, in Modification 5, the interior of the plasma processing chamber 10 is cleaned before the cleaning in steps S231 to S239. As a result, the deposits accumulated on a connection surface 111c (see FIG. 10) between the substrate placement surface (central region 111a) and the ring placement surface (annular region 111b), the inner periphery of the edge ring ER, and the lower surface of the edge ring ER may be removed more efficiently while suppressing damage to the electrostatic chuck 1111.

Further, in Modification 5, the cleaning for the interior of the plasma processing chamber 10 is executed with the dummy wafer separated from the central region 111a. As a result, it is possible to efficiently remove the deposits accumulated on the connection surface between the substrate placement surface and the ring placement surface.

In the cleaning process shown in FIG. 16, the processes of steps S221 to S223 shown in FIG. 8 may be performed instead of the processes of steps S238 and S239. After the process of step S223, the edge ring for replacement ER may be electrostatically attracted to the annular region 111b.

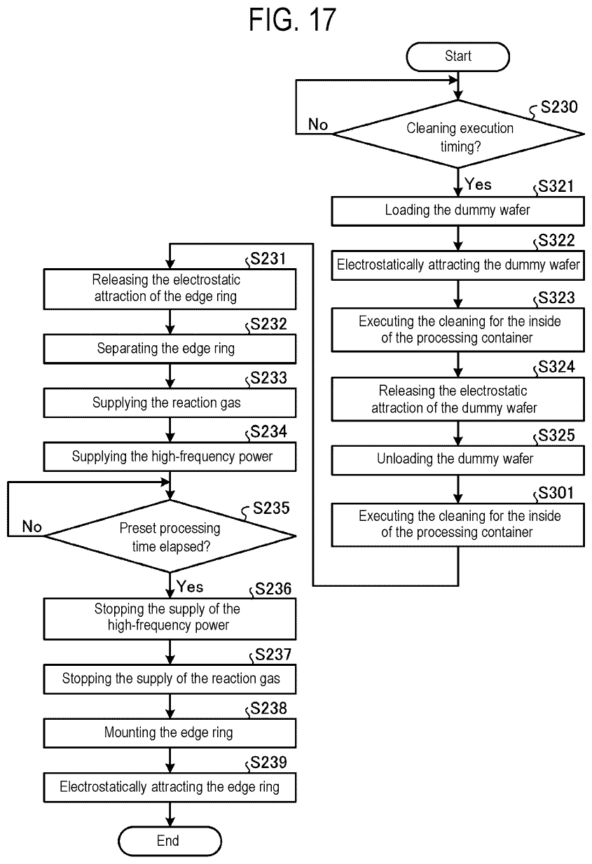

FIG. 17 is a flowchart showing an example of a flow of a cleaning process according to Modification 6 of the second embodiment. The cleaning process illustrated in FIG. 17 is implemented mainly by the PM 1 operating under the control of the controller 9. Steps S230 to S239 shown in FIG. 17 are the same as steps S230 to S239 shown in FIG. 11. Therefore, detailed descriptions thereof will be omitted herein. Further, since step S301 shown in FIG. 17 is the same as step S301 shown in FIG. 13, detailed descriptions thereof will be omitted herein.

In the cleaning process shown in FIG. 17, when it is determined that the timing to execute the cleaning process has arrived (S230: Yes), a dummy wafer is loaded into the plasma processing chamber 10 (S321). In step S321, the gate valve G4 is open, and the dummy wafer is carried out from the accommodation device 52 by the transfer robot 510. Then, the gate valve G1 is open, and the dummy wafer is loaded into the PM 1 and delivered to the lift pins 60. Then, the lift pins 60 are lowered by driving the elevating mechanism 62, so that the dummy wafer is placed on the central region 111a of the electrostatic chuck 1111. In this case, the diameter of the dummy wafer placed on the central region 111a in step S321 is the same as the diameter of the wafer W, and is larger than the inner diameter of the edge ring ER.

Subsequently, the dummy wafer is electrostatically attracted to the central region 111a (S322). Then, cleaning for the interior of the plasma processing chamber 10 is executed (S323). In step S323, the interior of the plasma processing chamber 10 is cleaned with the dummy wafer placed on the central region 111a. In step S323, a reaction gas (cleaning gas) is supplied from the gas supplier 20 into the plasma processing chamber 10, and radio-frequency power is supplied to the base 1110. As a result, in step S323, plasma of the cleaning gas is generated inside the plasma processing chamber 10, and the interior of the plasma processing chamber 10 is cleaned by the plasma generated from the cleaning gas.

The cleaning gas supplied into the plasma processing chamber 10 in step S323 may be the same as or different from the cleaning gas supplied into the plasma processing chamber 10 in step S233. The cleaning executed in step S323 is an example of a first cleaning.

When the cleaning in step S323 is completed, the application of the voltage to the first electrode 1111b is stopped, thereby releasing the electrostatic attraction of the dummy wafer to the central region 111a (S324).

Subsequently, the dummy wafer is unloaded (S325). In step S325, the elevating mechanism 62 is driven to raise the lift pins 60, thereby lifting the dummy wafer. Then, the gate valve G1 is open, and the dummy wafer is unloaded from the PM 1 by the transfer robot 510.

Subsequently, cleaning in step S301 is executed. The cleaning executed in step S301 is an example of a first cleaning.

When the cleaning in step S301 is completed, cleaning in steps S231 to S239 is executed. The cleaning executed in steps S231 to S239 is an example of a second cleaning.

As described above, in Modification 6, the interior of the plasma processing chamber 10 is cleaned before the cleaning in steps S231 to S239. This makes it possible to more efficiently remove the deposits accumulated on the outer periphery of the electrostatic chuck 1111, the inner periphery of the edge ring ER, and the lower surface of the edge ring ER while suppressing damage to the electrostatic chuck 1111.

In the cleaning process shown in FIG. 17, the processes of steps S221 to S223 in FIG. 8 may be performed instead of the processes of steps S238 and S239. After the process of step S223, the edge ring for replacement ER may be electrostatically attracted to the annular region 111b.

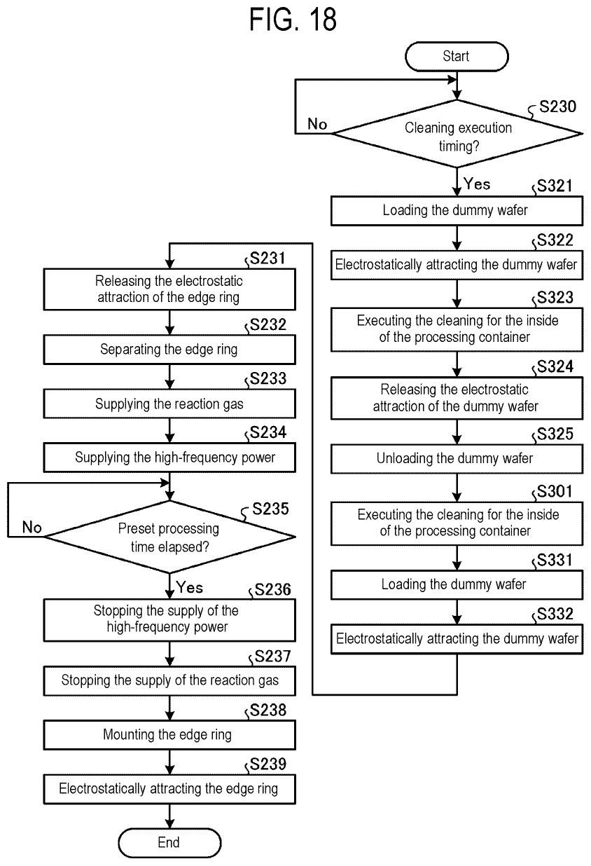

FIG. 18 is a flowchart showing an example of a flow of a cleaning process according to Modification 7 of the second embodiment. The cleaning process illustrated in FIG. 18 is implemented mainly by the PM 1 operating under the control of the controller 9. Steps S230 to S239 shown in FIG. 18 are the same as steps S230 to S239 shown in FIG. 11. Therefore, detailed descriptions thereof will be omitted herein. Further, since step S301 shown in FIG. 18 is the same as step S301 shown in FIG. 13, detailed descriptions thereof will be omitted herein. In addition, steps S321 to S325 shown in FIG. 18 are the same as steps S321 to S325 shown in FIG. 17, detailed descriptions thereof will be omitted herein.

In the cleaning process shown in FIG. 18, when the cleaning in step S301 is completed, a dummy wafer is loaded into the plasma processing chamber 10 (S331). In step S331, the gate valve G4 is open, and the dummy wafer is carried out from the accommodation device 52 by the transfer robot 510. Then, the gate valve G1 is open, and the dummy wafer is loaded into the PM 1 and delivered to the lift pins 60. Then, the lift pins 60 are lowered by driving the elevating mechanism 62, so that the dummy wafer is placed on the central region 111a of the electrostatic chuck 1111. In this case, the diameter of the dummy wafer placed on the central region 111a in step S331 is smaller than the inner diameter of the edge ring ER. Therefore, even when the dummy wafer is placed on the central region 111a, the edge ring ER may be separated from the annular region 111b without interference between the dummy wafer and the edge ring ER.

Subsequently, the dummy wafer is electrostatically attracted to the central region 111a (S332). Then, cleaning (second cleaning) in steps S231 to S239 is executed. In steps S231 to S239, the interior of the plasma processing chamber 10 is cleaned with the dummy wafer placed on the central region 111a.

As described above, in Modification 7, the interior of the plasma processing chamber 10 is cleaned before the cleaning in steps S231 to S239. This makes it possible to more efficiently remove the deposits accumulated on the outer periphery of the electrostatic chuck 1111, the inner periphery of the edge ring ER, and the lower surface of the edge ring ER while suppressing damage to the electrostatic chuck 1111.

Further, in Modification 7, the cleaning in steps S231 to S239 is executed with the dummy wafer placed on the central region 111a. Thus, even if the interior of the plasma processing chamber 10 is cleaned under conditions that provide high cleaning performance, it is possible to reduce damage to the central region 111a.

In the cleaning process shown in FIG. 18, the processes of steps S221 to S223 shown in FIG. 8 may be performed instead of the processes of steps S238 and S239. After the process of step S223, the edge ring for replacement ER may be electrostatically attracted to the annular region 111b.

Step S332 and step S231 may be executed at the same timing. That is, the electrostatic attraction of the edge ring ER to the annular region 111b may be released in parallel with the electrostatic attraction of the dummy wafer to the central region 111a. In this case, for example, after the dummy wafer is placed on the central region 111a, a gas such as a nitrogen gas or an oxygen gas may be supplied into the plasma processing chamber 10 to control the internal pressure of the plasma processing chamber 10 to a predetermined pressure, and radio-frequency power may be supplied to the plasma processing chamber 10 to generate plasma. In this state, a voltage may be applied to the first electrode 1111b (see FIG. 10) to electrostatically attract the dummy wafer to the central region 111a, and a voltage of opposite polarity to the voltage for electrostatic attraction may be applied to the second electrode 1111c to release the electrostatic attraction of the edge ring ER to the annular region 111b. Although the plasma is generated, an inert gas (nitrogen, or the like) may be supplied into the plasma processing chamber 10 to control the internal pressure of the plasma processing chamber 10 to a predetermined pressure (without generating plasma). In this state, the electrostatic attraction of the dummy wafer and the release of the electrostatic attraction of the edge ring may be performed.

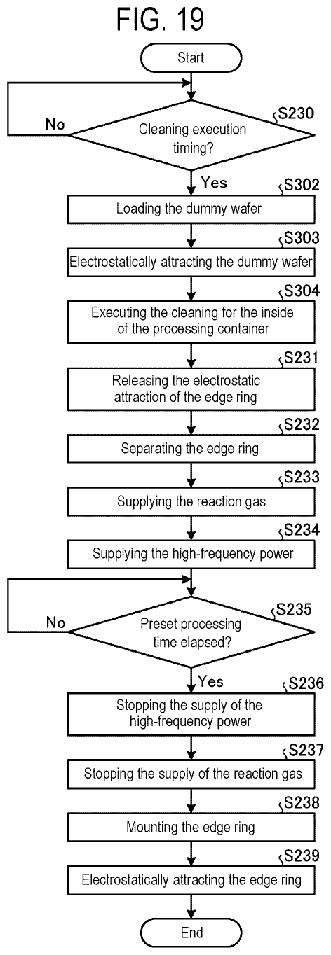

FIG. 19 is a flowchart showing an example of a flow of a cleaning process according to Modification 8 of the second embodiment. The cleaning process illustrated in FIG. 19 is implemented mainly by the PM 1 operating under the control of the controller 9. Steps S230 to S239 shown in FIG. 19 are the same as steps S230 to S239 shown in FIG. 11. Therefore, detailed descriptions thereof will be omitted herein. Further, since steps S302 to S303 shown in FIG. 19 are the same as steps S302 to S303 shown in FIG. 14, detailed descriptions thereof will be omitted herein.

In the cleaning process shown in FIG. 19, when the dummy wafer is electrostatically attracted to the central region 111a (S303), the interior of the plasma processing chamber 10 is cleaned (S304). In step S304, the interior of the plasma processing chamber 10 is cleaned with the dummy wafer placed on the central region 111a. In this case, the diameter of the dummy wafer placed on the central region 111a is smaller than the inner diameter of the edge ring ER. In step S304, a reaction gas (cleaning gas) is supplied from the gas supplier 20 into the plasma processing chamber 10, and radio-frequency power is supplied to the base 1110. As a result, in step S304, plasma of the cleaning gas is generated inside the plasma processing chamber 10, and the interior of the plasma processing chamber 10 is cleaned by the plasma generated from the cleaning gas.

The cleaning gas supplied into the plasma processing chamber 10 in step S304 may be the same as or different from the cleaning gas supplied into the plasma processing chamber 10 in step S233. The cleaning executed in step S304 is an example of a first cleaning.

When the cleaning in step S304 is completed, cleaning in steps S231 to S239 is executed. The cleaning executed in steps S231 to S239 is an example of a second cleaning. In steps S231 to S239, the interior of the plasma processing chamber 10 is cleaned with the dummy wafer placed on the central region 111a.

As described above, in Modification 8, the interior of the plasma processing chamber 10 is cleaned before the cleaning in steps S231 to S239. This makes it possible to more efficiently remove the deposits accumulated on the outer periphery of the electrostatic chuck 1111, the inner periphery of the edge ring ER, and the lower surface of the edge ring ER while suppressing damage to the electrostatic chuck 1111.

Further, in Modification 8, the cleaning in steps S231 to S239 is executed with the dummy wafer placed on the central region 111a. Thus, even if the interior of the plasma processing chamber 10 is cleaned under conditions that provide high cleaning performance, it is possible to reduce damage to the central region 111a.

In the cleaning process shown in FIG. 19, the processes of steps S221 to S223 shown in FIG. 8 may be performed instead of the processes of steps S238 and S239. After the process of step S223, the edge ring for replacement ER may be electrostatically attracted to the annular region 111b.

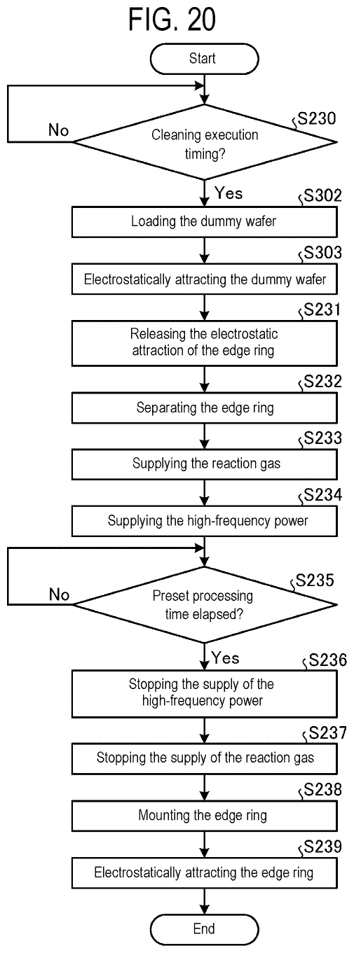

FIG. 20 is a flowchart showing an example of a flow of a cleaning process according to Modification 9 of the second embodiment. The cleaning process illustrated in FIG. 20 is implemented mainly by the PM 1 operating under the control of the controller 9. Steps S230 to S239 shown in FIG. 20 are the same as steps S230 to S239 shown in FIG. 11. Therefore, detailed descriptions thereof will be omitted herein. Further, since steps S302 to S303 shown in FIG. 20 are the same as steps S302 to S303 shown in FIG. 14, detailed descriptions thereof will be omitted herein.

In the cleaning process shown in FIG. 20, when the dummy wafer is electrostatically attracted to the central region 111a (S303), the cleaning (second cleaning) in steps S231 to S239 is executed. In steps S231 to S239, the interior of the plasma processing chamber 10 is cleaned with the dummy wafer placed on the central region 111a.

In Modification 9, the cleaning in steps S231 to S239 is executed with the dummy wafer placed on the central region 111a. Thus, even if the interior of the plasma processing chamber 10 is cleaned under conditions that provide high cleaning performance, it is possible to reduce damage to the central region 111a.

In the cleaning process shown in FIG. 20, the processes of steps S221 to S223 shown in FIG. 8 may be performed instead of the processes of steps S238 and S239. After the process of step S223, the edge ring for replacement ER may be electrostatically attracted to the annular region 111b.

Further, step S303 and step S231 may be executed at the same timing. That is, the electrostatic attraction of the edge ring ER to the annular region 111b may be released in parallel with the electrostatic attraction of the dummy wafer to the central region 111a. In this case, for example, after the dummy wafer is placed on the central region 111a, a gas such as a nitrogen gas or an oxygen gas may be supplied into the plasma processing chamber 10 to control the internal pressure of the plasma processing chamber 10 to a predetermined pressure, and radio-frequency power may be supplied to the plasma processing chamber 10 to generate plasma. In this state, a voltage may be applied to the first electrode 1111b (see FIG. 10) to electrostatically attract the dummy wafer to the central region 111a, and a voltage of opposite polarity to the voltage for electrostatic attraction may be applied to the second electrode 1111c to release the electrostatic attraction of the edge ring ER to the annular region 111b. Although the plasma is generated, an inert gas (nitrogen, or the like) may be supplied into the plasma processing chamber 10 to control the internal pressure of the plasma processing chamber 10 to a predetermined pressure (without generating plasma). In this state, the electrostatic attraction of the dummy wafer and the release of the electrostatic attraction of the edge ring may be performed.

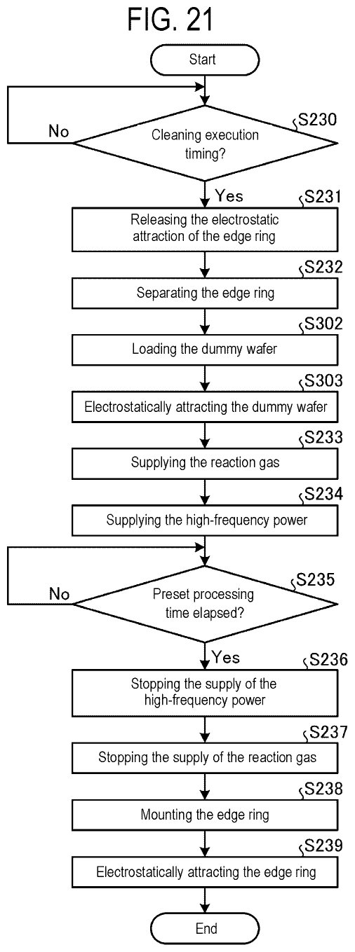

FIG. 21 is a flowchart showing an example of a flow of a cleaning process according to Modification 10 of the second embodiment. The cleaning process illustrated in FIG. 21 is implemented mainly by the PM 1 operating under the control of the controller 9. Steps S230 to S239 shown in FIG. 21 are the same as steps S230 to S239 shown in FIG. 11. Therefore, detailed descriptions thereof will be omitted herein. Further, since steps S302 to S303 shown in FIG. 20 are the same as steps S302 to S303 shown in FIG. 14, detailed descriptions thereof will be omitted herein.

In the cleaning process shown in FIG. 21, after the edge ring ER is separated from the annular region 111b by pining-up the lift pins 61 (S232), the dummy wafer is loaded into the plasma processing chamber 10 (S302). In this case, the diameter of the dummy wafer loaded into the plasma processing chamber 10 in step S302 is smaller than the inner diameter of the edge ring ER.

Subsequently, the dummy wafer is delivered to the lift pins 60 by raising (pining-up) the lift pins 60 with the driving of the elevating mechanism 62.

Subsequently, the lift pins 60 are lowered by driving the elevating mechanism 62, so that the dummy wafer is placed on the central region 111a and electrostatically attracted to the central region 111a (S303). Then, after the separation distance between the edge ring ER and the annular region 111b is adjusted as necessary, the processes of step S233 and subsequent steps are executed. That is, in the processes of step S233 and subsequent steps, the interior of the plasma processing chamber 10 is cleaned with the dummy wafer placed on the central region 111a.

In Modification 10, the processes of step S233 and subsequent steps are performed with the dummy wafer placed on the central region 111a. Thus, even if the interior of the plasma processing chamber 10 is cleaned under conditions that provide high cleaning performance, it is possible to reduce damage to the central region 111a.

Further, when the edge ring ER is separated from the annular region 111b after the dummy wafer is placed on the central region 111a, the dummy wafer and the edge ring ER may interfere with each other depending on the placement position of the dummy wafer on the central region 111a. In contrast, in Modification 10, the interference between the dummy wafer and the edge ring ER may be avoided by placing the dummy wafer on the central region 111a after separating the edge ring ER from the annular region 111b.

### Others

In the embodiments described above, the dummy wafer is accommodated in the accommodation device 52 provided separately from the VTM 51. However, the disclosed technique is not limited thereto. In another embodiment, the dummy wafer may be accommodated in a space provided inside the VTM 51. Further, the edge ring for replacement ER may also be accommodated in this space. Alternatively, the dummy wafer may be accommodated in a container such as a FOUP connected to the load port 55.

Further, in the above-described embodiment, the PM 1 that performs a process on the wafer W with plasma has been described as an example. However, the disclosed technique is not limited thereto. The disclosed technique may also be applied to an apparatus that does not use plasma, as long as the apparatus performs a process such as film formation or heat treatment on the wafer W.

Further, in the above-described embodiments, the capacitively coupled plasma was described as an example of a plasma source used for the PM 1. However, the plasma source is not limited thereto. Examples of plasma sources other than the capacitively coupled plasma may include inductively coupled plasma (ICP), microwave excited surface wave plasma (SWP), electron cyclotron resonance plasma (ECP), and helicon wave excited plasma (HWP). Microwaves used in the microwave excited surface wave plasma (SWP) are an example of electromagnetic waves.

According to the present disclosure, it is possible to remove deposits accumulated on an outer periphery of a stage, an inner periphery of a ring member, and a lower surface of a ring member while suppressing damage to the stage.

The embodiments disclosed herein should be considered to be exemplary in all respects and not limitative. Indeed, the embodiments described above may be implemented in various forms. Further, the above-described embodiments may be omitted, replaced, or modified in various forms without departing from the scope and spirit of the appended claims.

Regarding the above-described embodiments, the following supplementary notes are further provided.

### Supplementary Note 1

A plasma processing apparatus, comprising:
a stage having a first placement surface on which a substrate is placed, and a second placement surface on which a ring member surrounding an outer periphery of the first placement surface is placed;
an elevating mechanism configured to raise and lower the ring member with respect to the second placement surface;
a radio-frequency power source connected to the stage; and
a controller,
wherein the controller is configured to execute a cleaning process that includes:
   a separation operation of separating the second placement surface and the ring member from each other by the elevating mechanism; and
   subsequently, a removal operation of removing deposits accumulated on the stage and the ring member by supplying radio-frequency power from the radio-frequency power source to the stage to generate plasma, and
   wherein in the separation operation, a separation distance between the second placement surface and the ring member is set such that a first density of the plasma generated in a first region between an outer edge of the first placement surface and an inner edge of a lower surface of the ring member is higher than a second density of the plasma generated in a second region.

### Supplementary Note 2

In the plasma processing apparatus of Supplementary Note 1 above, in the separation operation, a height of the lower surface of the ring member with respect to the first placement surface is 1.4 mm or more and 4.4 mm or less.

### Supplementary Note 3

In the plasma processing apparatus of Supplementary Note 2 above, in the separation operation, the height of the lower surface of the ring member with respect to the first placement surface is 1.6 mm or more and 3.4 mm or less.

### Supplementary Note 4

In the plasma processing apparatus of Supplementary Note 3 above, in the separation operation, the height of the lower surface of the ring member with respect to the first placement surface is 2.0 mm or more and 2.8 mm or less.

### Supplementary Note 5

In the plasma processing apparatus of any one of Supplementary Notes 1 to 4 above, the controller is configured to further execute:
an additional separation operation of further separating the second placement surface and the ring member from each other by the elevating mechanism after executing the cleaning process including the separation operation and the removal operation; and
subsequently, an additional removal operation of further removing the deposits accumulated on the stage and the ring member by supplying the radio-frequency power from the radio-frequency power source to the stage to generate the plasma.

### Supplementary Note 6

In the plasma processing apparatus of Supplementary Note 5 above, in the additional separation operation, a height of the lower surface of the ring member with respect to the first placement surface is 6.4 mm or more and 32.4 mm or less.

### Supplementary Note 7

In the plasma processing apparatus of Supplementary Note 6 above, in the additional separation operation, the height of the lower surface of the ring member with respect to the first placement surface is 12.4 mm or more and 32.4 mm or less.

### Supplementary Note 8

In the plasma processing apparatus of any one of Supplementary Notes 1 to 7 above, the stage includes an electrode configured to electrostatically attract the ring member.

### Supplementary Note 9

In the plasma processing apparatus of any one of Supplementary Notes 1 to 8 above, the cleaning process is executed in a state in which the substrate is not placed on the first placement surface.

### Supplementary Note 10

In the plasma processing apparatus of any one of Supplementary Notes 1 to 8 above, the cleaning process is executed in a state in which a dummy substrate is placed on the first placement surface.

### Supplementary Note 11

In the plasma processing apparatus of Supplementary Note 10 above, a diameter of the dummy substrate is smaller than an inner diameter of the ring member.

### Supplementary Note 12

In the plasma processing apparatus of Supplementary Note 1 above, when the cleaning process including the separation operation and the removal operation is a second cleaning process, before the second cleaning process, the controller is configured to further execute a first cleaning process on an interior of a processing container accommodating the stage by supplying the radio-frequency power from the radio-frequency power source to the stage to generate the plasma.

### Supplementary Note 13

In the plasma processing apparatus of Supplementary Note 12 above, the first cleaning process is executed in a state in which a dummy substrate is placed on the first placement surface.

### Supplementary Note 14

The plasma processing apparatus of Supplementary Note 12 above further includes an additional elevating mechanism configured to raise and lower the substrate or a dummy substrate with respect to the first placement surface,
wherein the controller is configured to further execute a third cleaning process on the interior of the processing container between the first cleaning process and the second cleaning process by supplying the radio-frequency power from the radio-frequency power source to the stage to generate the plasma in a state in which the dummy substrate is held at a position spaced apart from the first placement surface using the additional elevating mechanism, and
wherein the second cleaning process is executed after the dummy substrate is unloaded from the processing container.

### Supplementary Note 15

In the plasma processing apparatus of Supplementary Note 12 above, the stage is configured such that the ring member is electrostatically attracted to the second placement surface,
wherein the first cleaning process is executed in a state in which the substrate is not placed on the first placement surface, and
wherein the electrostatic attraction of the ring member to the second placement surface is released in parallel with the first cleaning process.

### Supplementary Note 16

In the plasma processing apparatus of Supplementary Note 12 above, the second cleaning process is executed in a state in which a dummy substrate is placed on the first placement surface.

### Supplementary Note 17

In the plasma processing apparatus of Supplementary Note 16 above, the stage is configured such that the ring member is electrostatically attracted to the second placement surface,
wherein the first cleaning process is executed in a state in which the substrate is not placed on the first placement surface,
wherein the controller is configured to execute an operation of placing and electrostatically attracting the dummy substrate on the first placement surface after the first cleaning process, and
wherein the electrostatic attraction of the ring member to the second placement surface is released in parallel with the electrostatic attraction of the dummy substrate to the first placement surface.

### Supplementary Note 18

In the plasma processing apparatus of Supplementary Note 12 above, processing conditions for the second cleaning process are set by changing at least one parameter from processing conditions for the first cleaning process.

### Supplementary Note 19

In the plasma processing apparatus of Supplementary Note 12 above, processing conditions for the first cleaning process and the second cleaning process include at least one parameter selected from a group of parameters consisting of a gas type, a gas flow rate ratio, a gas flow rate, a pressure, bias power, plasma generation power, a temperature of the stage and a cleaning time.

### Supplementary Note 20

In the plasma processing apparatus of Supplementary Note 12 above, the plasma generation power supplied in the second cleaning process is greater than the plasma generation power supplied in the first cleaning process.

### Supplementary Note 21

In the plasma processing apparatus of Supplementary Note 12 above, the second cleaning process is executed at a higher pressure than the first cleaning process.

### Supplementary Note 22

In the plasma processing apparatus of Supplementary Note 12 above, the second cleaning process is executed with a higher bias power than the first cleaning process.

### Supplementary Note 23

In the plasma processing apparatus of Supplementary Note 12 above, a temperature of the stage in the second cleaning process is higher than a temperature of the stage in the first cleaning process.

### Supplementary Note 24

In the plasma processing apparatus of Supplementary Note 12 above, a cleaning time in the second cleaning process is longer than a cleaning time in the first cleaning process.

### Supplementary Note 25

In the plasma processing apparatus of Supplementary Note 12 above, in the first cleaning process and the second cleaning process, the plasma is generated from a cleaning gas including at least one selected from the group consisting of an O₂ gas, an O₃ gas, a CO gas, a CO₂ gas, a COS gas, an N₂ gas and an H₂ gas.

### Supplementary Note 26

In the plasma processing apparatus of Supplementary Note 25 above, in the second cleaning process, a halogen-containing gas is further supplied into the processing container.

### Supplementary Note 27

In the plasma processing apparatus of Supplementary Note 26 above, the halogen-containing gas is a CF₄ gas, an NF₃ gas, an SF₆ gas, a Cl₂ gas, or an HBr gas.

### Supplementary Note 28

The plasma processing apparatus of Supplementary Note 25 above further includes a heat transfer gas supplier configured to supply a heat transfer gas to a gap between the second placement surface and the ring member, wherein in the removal operation, the cleaning gas is supplied from the heat transfer gas supplier into the processing container instead of the heat transfer gas.

### Supplementary Note 29

In the plasma processing apparatus of Supplementary Note 28 above, in the removal operation, a halogen-containing gas is further supplied from the heat transfer gas supplier into the processing container.

### Supplementary Note 30

In the plasma processing apparatus of Supplementary Note 29 above, the halogen-containing gas is a CF₄ gas, an NF₃ gas, an SF₆ gas, a Cl₂ gas, or an HBr gas.

### Supplementary Note 31

In the plasma processing apparatus of Supplementary Note 26 above, in the first cleaning process, the halogen-containing gas is further supplied into the processing container, and a flow rate of the halogen-containing gas supplied into the processing container in the second cleaning process is higher than a flow rate of the halogen-containing gas supplied into the processing container in the first cleaning process.

### Supplementary Note 32

In the plasma processing apparatus of Supplementary Note 1 above, when the cleaning process including the separation operation and the removal operation is a second cleaning process, before the second cleaning process, the controller is configured to further execute a first cleaning process on an interior of a processing container accommodating the stage by supplying radio-frequency power from the radio-frequency power source to the stage to generate the plasma in a state in which a dummy substrate is placed on the first placement surface.

### Supplementary Note 33

In the plasma processing apparatus of Supplementary Note 1 above, the controller is configured to execute the cleaning process further including placing a dummy substrate on the first placement surface after the separation operation, and
the removal operation is executed after the placing.

### Supplementary Note 34

In the plasma processing apparatus of any one of Supplementary Notes 1 to 33 above, the ring member is an edge ring.

What is claimed is:

1. A plasma processing apparatus, comprising:
a stage having a first placement surface on which a substrate is placed, and a second placement surface on which a ring member surrounding an outer periphery of the first placement surface is placed;
an elevating mechanism configured to raise and lower the ring member with respect to the second placement surface;
a radio-frequency power source connected to the stage; and
a controller,
wherein the controller is configured to execute a cleaning process that includes:
a separation operation of separating the second placement surface and the ring member from each other by the elevating mechanism; and
subsequently, a removal operation of removing deposits accumulated on the stage and the ring member by supplying radio-frequency power from the radio-frequency power source to the stage to generate plasma, and
wherein in the separation operation, a separation distance between the second placement surface and the ring member is set such that a first density of the plasma generated in a first region between an outer edge of the first placement surface and an inner edge of a lower surface of the ring member is higher than a second density of the plasma generated in a second region.

2. The plasma processing apparatus of claim 1, wherein in the separation operation, a height of the lower surface of the ring member with respect to the first placement surface is 1.4 mm or more and 4.4 mm or less.

3. The plasma processing apparatus of claim 2, wherein in the separation operation, the height of the lower surface of the ring member with respect to the first placement surface is 1.6 mm or more and 3.4 mm or less.

4. The plasma processing apparatus of claim 3, wherein in the separation operation, the height of the lower surface of the ring member with respect to the first placement surface is 2.0 mm or more and 2.8 mm or less.

5. The plasma processing apparatus of claim 1, wherein the controller is configured to further execute:
an additional separation operation of further separating the second placement surface and the ring member from each other by the elevating mechanism after executing the cleaning process including the separation operation and the removal operation; and
subsequently, an additional removal operation of further removing the deposits accumulated on the stage and the ring member by supplying the radio-frequency power from the radio-frequency power source to the stage to generate the plasma.

6. The plasma processing apparatus of claim 5, wherein in the additional separation operation, a height of the lower surface of the ring member with respect to the first placement surface is 6.4 mm or more and 32.4 mm or less.

7. The plasma processing apparatus of claim 6, wherein in the additional separation operation, the height of the lower surface of the ring member with respect to the first placement surface is 12.4 mm or more and 32.4 mm or less.

8. The plasma processing apparatus of claim 1, wherein the stage includes an electrode configured to electrostatically attract the ring member.

9. The plasma processing apparatus of claim 1, wherein the cleaning process is executed in a state in which the substrate is not placed on the first placement surface.

10. The plasma processing apparatus of claim 1, wherein the cleaning process is executed in a state in which a dummy substrate is placed on the first placement surface.

11. The plasma processing apparatus of claim 10, wherein a diameter of the dummy substrate is smaller than an inner diameter of the ring member.

12. The plasma processing apparatus of claim 1, wherein, when the cleaning process including the separation operation and the removal operation is a second cleaning process, before the second cleaning process, the controller is configured to further execute a first cleaning process on an interior of a processing container accommodating the stage by supplying the radio-frequency power from the radio-frequency power source to the stage to generate the plasma.

13. The plasma processing apparatus of claim 12, wherein the first cleaning process is executed in a state in which a dummy substrate is placed on the first placement surface.

14. The plasma processing apparatus of claim 12, further comprising:
an additional elevating mechanism configured to raise and lower the substrate or a dummy substrate with respect to the first placement surface,
wherein the controller is configured to further execute a third cleaning process on the interior of the processing container between the first cleaning process and the second cleaning process by supplying the radio-frequency power from the radio-frequency power source to the stage to generate the plasma in a state in which the dummy substrate is held at a position spaced apart from the first placement surface using the additional elevating mechanism, and
wherein the second cleaning process is executed after the dummy substrate is unloaded from the processing container.

15. The plasma processing apparatus of claim 12, wherein the stage is configured such that the ring member is electrostatically attracted to the second placement surface,
wherein the first cleaning process is executed in a state in which the substrate is not placed on the first placement surface, and
wherein the electrostatic attraction of the ring member to the second placement surface is released in parallel with the first cleaning process.

16. The plasma processing apparatus of claim 12, wherein the second cleaning process is executed in a state in which a dummy substrate is placed on the first placement surface.

17. The plasma processing apparatus of claim 16, wherein the stage is configured such that the ring member is electrostatically attracted to the second placement surface,
wherein the first cleaning process is executed in a state in which the substrate is not placed on the first placement surface,
wherein the controller is configured to execute an operation of placing and electrostatically attracting the dummy substrate on the first placement surface after the first cleaning process, and
wherein the electrostatic attraction of the ring member to the second placement surface is released in parallel with the electrostatic attraction of the dummy substrate to the first placement surface.

18. The plasma processing apparatus of claim 12, wherein processing conditions for the second cleaning process are set by changing at least one parameter from processing conditions for the first cleaning process.

19. The plasma processing apparatus of claim 12, wherein processing conditions for the first cleaning process and the second cleaning process include at least one parameter selected from a group of parameters consisting of a gas type, a gas flow rate ratio, a gas flow rate, a pressure, bias power, plasma generation power, a temperature of the stage and a cleaning time.

20. The plasma processing apparatus of claim 12, wherein the plasma generation power supplied in the second cleaning process is greater than the plasma generation power supplied in the first cleaning process.

21. The plasma processing apparatus of claim 12, wherein the second cleaning process is executed at a higher pressure than the first cleaning process.

22. The plasma processing apparatus of claim 12, wherein the second cleaning process is executed with a higher bias power than the first cleaning process.

23. The plasma processing apparatus of claim 12, wherein a temperature of the stage in the second cleaning process is higher than a temperature of the stage in the first cleaning process.

24. The plasma processing apparatus of claim 12, wherein a cleaning time in the second cleaning process is longer than a cleaning time in the first cleaning process.

25. The plasma processing apparatus of claim 12, wherein in the first cleaning process and the second cleaning process, the plasma is generated from a cleaning gas including at least one selected from the group consisting of an O₂ gas, an O₃ gas, a CO gas, a CO₂ gas, a COS gas, an N₂ gas and an H₂ gas.

26. The plasma processing apparatus of claim 25, wherein in the second cleaning process, a halogen-containing gas is further supplied into the processing container.

27. The plasma processing apparatus of claim 26, wherein the halogen-containing gas is a CF₄ gas, an NF₃ gas, an SF₆ gas, a Cl₂ gas, or an HBr gas.

28. The plasma processing apparatus of claim 25, further comprising:
a heat transfer gas supplier configured to supply a heat transfer gas to a gap between the second placement surface and the ring member,
wherein in the removal operation, the cleaning gas is supplied from the heat transfer gas supplier into the processing container instead of the heat transfer gas.

29. The plasma processing apparatus of claim 28, wherein in the removal operation, a halogen-containing gas is further supplied from the heat transfer gas supplier into the processing container.

30. The plasma processing apparatus of claim 29, wherein the halogen-containing gas is a CF₄ gas, an NF₃ gas, an SF₆ gas, a Cl₂ gas, or an HBr gas.

31. The plasma processing apparatus of claim 26, wherein in the first cleaning process, the halogen-containing gas is further supplied into the processing container, and
wherein a flow rate of the halogen-containing gas supplied into the processing container in the second cleaning process is higher than a flow rate of the halogen-containing gas supplied into the processing container in the first cleaning process.

32. The plasma processing apparatus of claim 1, wherein, when the cleaning process including the separation operation and the removal operation is a second cleaning process, before the second cleaning process, the controller is configured to further execute a first cleaning process on an interior of a processing container accommodating the stage by supplying radio-frequency power from the radio-frequency power source to the stage to generate the plasma in a state in which a dummy substrate is placed on the first placement surface.

33. The plasma processing apparatus of claim 1, wherein the controller is configured to execute the cleaning process further including placing a dummy substrate on the first placement surface after the separation operation, and
wherein the removal operation is executed after the placing.

34. The plasma processing apparatus of claim 1, wherein the ring member is an edge ring.
